(19) United States
(12) Patent Application Publication
(10) Pub. No.: US 2018/0358352 A1
(43) Pub. Date: Dec. 13, 2018

(54) STRUCTURE, METHOD, AND CIRCUIT FOR ELECTROSTATIC DISCHARGE PROTECTION UTILIZING A RECTIFYING CONTACT

(71) Applicant: SILICET, LLC, Chapel Hill, NC (US)

(72) Inventor: Steven H VOLDMAN, Lake Placid, NY (US)

(21) Appl. No.: 16/003,611

(22) Filed: Jun. 8, 2018

Related U.S. Application Data
(60) Provisional application No. 62/517,114, filed on Jun. 8, 2017.

(51) Int. Cl. H01L 27/02; H01L 29/66; H01L 29/872

(52) U.S. Cl. CPC H01L 27/0255; H01L 29/872; H01L 29/66143

(57) ABSTRACT

A device and structure for providing electrostatic discharge (ESD) protection. Schottky barrier diode (SBD) structure comprising a substrate of a first dopant polarity, a well region of a second dopant polarity formed on or within said substrate, an anode region of a first dopant polarity, a cathode of a second polarity, and a rectifying contact on said anode and/or said cathode, wherein said rectifying contact is formed substantially near the surface of said substrate to provide a rectifying barrier junction between the conducting layer and the semiconductor substrate, providing electrical coupling in said Schottky Barrier diode structure. The disclosure further includes SOI Schottky Barrier polysilicon-bound diodes (also known as Lubistor structures). Additionally, a diode configured SOI dynamic threshold MOSFET with rectifying barrier junctions on the drain or source region.

### CROSS-REFERENCE TO RELATED APPLICATIONS

The present application is a non-provisional patent application of, and claims the benefit under 35 U.S.C § 119(e) to U.S. Provisional Patent Application No. 62/517,114, filed Jun. 8, 2017, the entirety of which is expressly incorporated herein by reference.

### COPYRIGHT STATEMENT

All of the material in this patent document is subject to copyright protection under the copyright laws of the United States and of other countries. The copyright owner has no objection to the facsimile reproduction by anyone of the patent document or the patent disclosure, as it appears in the Patent and Trademark Office patent file or records, but otherwise reserves all copyright rights whatsoever.

### BACKGROUND OF THE PRESENT INVENTION

### Field of the Present Invention

The disclosure relates generally to a structure and corresponding methods of formation, more particularly, to a device for electrostatic discharge (ESD) protection and circuits that improve reliability and ESD robustness.

### Background

Electrostatic discharge (ESD) devices and circuits are needed for semiconductor components. ESD and electrical overstress (EOS) phenomena occurs in manufacturing, handling, shipping, and the application environment. ESD models for components and systems practiced today includes human body model (HBM), machine model (MM), charged device model (CDM), charged board model (CBM), and cable discharge event (CDE). Testing for qualification includes transmission line pulse (TLP) and very fast transmission line pulse (VF-TLP) models, human metal model (HMM), IEC 61000-4-2, and IEC 61000-4-5. ESD pulse events are on the order of the application frequency of digital and analog circuitry. ESD protection devices are used in different technology types from bipolar, complementary metal oxide semiconductors (CMOS), bipolar/CMOS (BiCMOS), silicon on insulator (SOI), silicon germanium (SiGe), and double-diffused MOS (DMOS).

ESD protection circuit elements are used for different application types based on the functional requirements of the circuit. ESD protection networks are needed in digital, analog, and radio frequency (RF) applications. For digital CMOS circuits, key design requirements are ESD protection design area and loading capacitance. For analog CMOS circuits, ESD design requirements include linearity and matching. For RF technologies, ESD design requirements include area, capacitance load, linearity, and signal swing. Radio frequency (RF) ESD networks are significantly different from digital and analog ESD networks. ESD pulse events are on the order of the application frequency of digital and analog circuitry. ESD pulse phenomena is less than 5 GHz. Hence, ESD phenomena is faster than digital and analog application frequency. But, today's RF application frequencies are faster than ESD phenomena. (As used herein, radio frequency (RF) refers to the oscillation rate of electromagnetic waves in the range of 3 kHZ to 300 GHz that include frequencies used for communications signals (e.g. radio and TV broadcasting, cellphone, WiFi and satellite transmission) or radar signals.) As a result, ESD circuit solutions for digital and analog are not acceptable for RF applications. Digital and analog ESD circuits utilize resistor and capacitor elements. From an RF perspective, the resistors generate noise which is not acceptable for RF applications. Capacitor elements are frequency dependent and lower the impedance of RF applications. The impedance of a capacitor is proportional to the inverse product of the frequency and the capacitance. As the application frequency increases, the impedance decreases, which is undesirable. RF ESD networks must have low capacitance to minimize this issue. Hence, low capacitance diode elements that have low resistance are required to provide a high ESD robustness per loading capacitance.

Radio frequency technologies can include both bulk CMOS or SOI technology. Bulk technologies can be inclusive of CMOS and BiCMOS technology. SOI technologies can include partially-depleted SOI (PD-SOI), fully depleted SOI (FD-SOI), and ultra-thin SOI (UT-SOI). These technologies also can use standard CMOS or dynamic threshold MOS (DTMOS) technology. In each technology type, different devices are required.

Scaling CMOS technologies to smaller channel lengths has been accompanied by increasing operating frequencies and a corresponding proliferation of high data rate and speciality Input/Output circuits. These high-speed interface circuit application frequencies can exceed the frequency of electrostatic discharge (ESD) and electrical overstress (EOS) phenomenon. The “ideal ESD network” from a frequency perspective has a low impedance during ESD events (e.g. sub 5 GHz frequencies) and high impedance during RF application frequency. This can be achieved using combination of capacitor and inductor elements. RF ESD networks must not limit the linearity, capacitance, or area of the circuit. These high-speed interface and Input/Output (I/O) circuits require ESD protection to survive manufacturing and handling issues. They must also have a good ESD robustness per loading capacitance (e.g.—ESD per femtoFarad) metric.

FIG. 1 is a cross-section of a prior art shallow trench isolation (STI)-defined bulk CMOS p-n diode structure 100 used for ESD protection. The structure 100 contains a p-Substrate wafer 105 and an n-Well region 110. The structure further includes a p+ region, forming an anode 120, and an n+ cathode 130. The p+ anode 120 and n+ cathode 130 are defined by shallow trench isolation (STI) structures 140. Ohmic contact regions 115 are formed on the p+ anode 120 and the n+ cathode 130 using standard metallization techniques. A substrate contact 107 with an ohmic contact region 115 is also provided to electrically connect to the substrate 105. Metallization layers and interlevel dielectric (ILD) are placed on the wafer surface. Shallow trench isolation (STI)-bound diode structures 100 may be used for ESD protection in bulk CMOS technology and RF technology. Such a structure can also be used in SOI technology by forming the structure on an SOI wafer. However, the STI-bound diode structure has an anode and cathode capacitance which is undesirable for radio frequency applications. For example, the diode impedance due to capacitance is equal to the inverse of the frequency and capacitance product. This is a concern in RF applications due to the change in the input impedance of RF circuits.

FIG. 2 is a cross-section of a prior art polysilicon gate defined lateral bulk CMOS p-n diode structure 200 used for ESD protection. The structure 200 contains a p-Substrate wafer 205 and an n-Well region 210. The structure further includes a p+ region, forming an anode 220, and an n+ region forming a cathode 230. A thin gate oxide or other gate dielectric layer 242 is formed on top of the n-Well 210, and the well is partially covered by a gate structure 240. The gate stack film of the polysilicon gate structure 240 contains a p+ implant on the side of the p+ anode 220, and an n+ implant on the side of the n+cathode 230. The p+ and n+ implants contained within the gate stack film are artifacts of the formation of p+ anode 220 and the n+ cathode 230 regions, and do not affect device operation. Spacer structures 237 are located on the sidewalls of the gate structure 240. The p+ anode 220 and n+ cathode 230 are defined by the gate structure 240 and spacers 237. Ohmic contact regions 215 are formed on the p+ anode 220 and n+ cathode 230 using standard metallization techniques. A substrate contact 207 with an ohmic contact region 215 is also provided to electrically connect to the substrate 205 with STI regions 250 isolating ohmic contact regions 215. Metallization layers and interlevel dielectric (ILD) are placed on the wafer surface. Polysilicon-bound diode structures may be used for ESD protection in bulk CMOS technology and RF technology. Such a structure can also be formed in SOI technology on an SOI wafer. However, the polysilicon bound diode structure has an anode and cathode capacitance which is undesirable for radio frequency applications. For example, the diode impedance due to capacitance is equal to the inverse of the frequency and capacitance product. This is a concern in RF applications due to the change in the input impedance of RF circuits.

Various prior art diode structures are known. For example, U.S. Pat. No 5,629,544 to Voldman et al., describes a semiconductor diode structure with silicide film and trench isolation. This patent describes a diode with a shallow trench isolation defining the anode and cathode. U.S. 2005/00035410 to Yeo et al., describes a semiconductor diode comprising a polysilicon gate and a p+ anode, and n+ cathode. This application discusses the lateral diode structure. U.S. Pat. No. 5,811,857 to Assaderaghi et al., describes a dynamic threshold MOS (DTMOS) device with the body, gate and source coupled.

In these prior art embodiments, the solution to establish a structure, device and methods utilized various alternative solutions. However, each has one or more shortcomings. Thus, a need exists for improvements in structures, circuits, and methods for electrostatic discharge protection.

### SUMMARY OF THE PRESENT INVENTION

Broadly defined, the present invention according to one aspect involves a diode structure including: a substrate defining a wafer surface; a well region formed on or within said substrate; an isolation structure substantially near said substrate wafer surface; an anode, of a first dopant polarity, defined by said isolation structure in said well region formed on or within said substrate; a cathode, of a second dopant polarity, defined by said isolation structure; and a rectifying contact on at least one of the anode and the cathode, wherein the rectifying contact is a Schottky or Schottky-like contact formed substantially near the wafer surface.

In a feature related to this aspect, said isolation structure includes a shallow trench isolation (STI) structure having a surface, wherein the surface of said isolation structure is substantially co-planar to said substrate wafer surface.

In another feature related to this aspect, said isolation structure includes a gate structure and a spacer structure. In further features, said diode structure is a polysilicon-gate defined diode Lubistor structure; the Schottky or Schottky-like contact is a pure metal, a pure metal alloy, or a silicide-to-semiconductor interface; the Schottky or Schottky-like contact is substantially near said gate structure to provide reduced electrical resistance relative to a conventional p-n diode structure; the Schottky or Schottky-like contact provides reduced electrical capacitance relative to a conventional p-n diode structure; the spacer structure abuts a sidewall of said gate structure and adjusts the electrical coupling to the rectifying contact; the Schottky or Schottky-like contact has a band structure that is modulated with anneal parameters, and wherein the anneal parameters comprise a temperature and/or a time; the Schottky or Schottky-like contact has a band structure that is modulated by dopant segregation implantation dose and/or dopant segregation implantation energy; the rectifying contact is formed from a refractory metal, and wherein said refractory metal includes one or more of Co, Ni, Ni/Pt, Pd, Pt, Ta, TaN, Ti, TiN, and W; said well region has a dopant polarity that is the same dopant polarity as the cathode, thereby providing a p+/n−/n+ diode; said well region has a dopant polarity that is the same dopant polarity as the anode, thereby providing a p+/p−/n+ diode; and/or said well region includes a first well region and a second well region, wherein the first well region has a dopant polarity that is the same dopant polarity as the anode, and wherein the second well region has a dopant polarity that is the same dopant polarity as the cathode, thereby providing a p+/p−/n−/n+ diode.

Broadly defined, the present invention according to another aspect involves a diode structure including: a silicon on insulator (SOI) wafer that includes a substrate, supporting a buried oxide (BOX) layer and a silicon film above said BOX layer, and defining a wafer surface; a gate structure and a spacer structure on said silicon on insulator (SOI) wafer; a region of a first dopant polarity, forming an anode, defined by said gate structure and spacer structure, formed in said SOI wafer; a region of a second dopant polarity, forming a cathode, defined by said gate structure and spacer structure; and a rectifying contact on at least one of the anode and the cathode, wherein the rectifying contact is a Schottky or Schottky-like contact formed substantially near the wafer surface.

In a feature related to this aspect, the Schottky or Schottky-like contact is substantially near said gate structure to provide reduced electrical resistance relative to a conventional p-n diode structure.

In another feature related to this aspect, the spacer structure abuts a sidewall of said gate structure and adjusts the electrical coupling to the rectifying contact.

In another feature related to this aspect, said diode structure provides a p+/n−/n+ diode.

In another feature related to this aspect, said diode structure provides a p+/p−/n+ diode.

In another feature related to this aspect, said diode structure provides a p+/p−//n−/n+ diode.

Broadly defined, the present invention according to another aspect involves a dynamic threshold Schottky Barrier MOS (DTSBMOS) including: a silicon on insulator (SOI) wafer that includes a substrate, supporting a buried oxide (BOX) layer and a silicon film above said BOX layer, wherein said silicon film forms a body of a first dopant polarity, and defining a wafer surface; a gate structure and a spacer structure on said silicon on insulator (SOI) wafer; a source region of a second dopant polarity defined adjacent to said gate structure; a drain region of the second dopant polarity defined adjacent to said gate structure; and a rectifying contact on at least one of the source and the drain region wherein the rectifying contact is a Schottky or Schottky-like contact formed substantially near the wafer surface; wherein said gate structure and said body are electrically interconnected.

In a feature related to this aspect, said gate structure and said body are electrically connected to said source to form a dynamic threshold Schottky Barrier MOS diode.

In another feature related to this aspect, the Schottky or Schottky-like contact on the drain region is a first Schottky or Schottky-like contact, and wherein a second Schottky or Schottky-like contact is formed on the source region. In a further feature, said silicon on insulator (SOI) wafer is an ultra-thin SOI (UTSOI) wafer.

In another feature related to this aspect, the Schottky-like contact is substantially near said gate structure to provide reduced electrical resistance relative to a conventional p-n diode structure.

In another feature related to this aspect, the spacer structure abuts a sidewall of said gate structure and adjusts the electrical coupling to the rectifying contact.

In another feature related to this aspect, the Schottky or Schottky-like contact has a band structure that is modulated with anneal parameters, and wherein the anneal parameters comprise a temperature and/or a time.

In another feature related to this aspect, the Schottky or Schottky-like contact has a band structure that is modulated by dopant segregation implantation dose and/or dopant segregation implantation energy.

Broadly defined, the present invention according to another aspect involves a method of forming a Shallow Trench Isolation Schottky Barrier diode (STISBD) structure, including the steps of: providing a silicon on insulator (SOI) wafer that includes a substrate, supporting a buried oxide (BOX) layer and a silicon film above said BOX layer, and defining a wafer surface; forming a gate structure and a spacer structure on said silicon on insulator (SOI) wafer; forming an anode region, of a first dopant polarity, in the SOI wafer; forming a cathode region, of a second dopant polarity, in the SOI wafer, wherein the anode and the cathode are defined by said gate structure and spacer structure; and forming a rectifying contact on at least one of the anode and the cathode, wherein the rectifying contact is a Schottky or Schottky-like contact formed substantially near the wafer surface.

In a feature related to this aspect, the Schottky or Schottky-like contact is substantially near said gate structure to provide reduced electrical resistance relative to a conventional p-n diode structure.

In another feature related to this aspect, the spacer structure abuts a sidewall of said gate structure, and wherein the method further includes adjusting the electrical coupling to the rectifying contact via the spacer structure.

In another feature related to this aspect, the diode structure formed by the method provides a p+/n−/n+ diode.

In another feature related to this aspect, the diode structure formed by the method provides a p+/p−/In+ diode.

In another feature related to this aspect, the diode structure formed by the method provides a p+/p−/n−/n+ diode.

Broadly defined, the present invention according to another aspect involves a method of forming a Shallow Trench Isolation Schottky Barrier diode (STISBD) structure, including the steps of: providing a substrate defining a wafer surface; forming a well region on or within said substrate; forming an isolation structure substantially near said substrate wafer surface; implanting an anode, of a first dopant polarity, in said well region; implanting a cathode, of a second dopant polarity, in said well region, wherein the cathode is defined by the isolation structure; forming a rectifying contact on at least one of the anode and the cathode, wherein the rectifying contact is a Schottky or Schottky-like contact formed substantially near the wafer surface; and patterning and defining inter-level dielectric (ILD) and interconnect wiring on the wafer surface.

In a feature related to this aspect, the method further includes a step of patterning and defining inter-level dielectric (ILD) and interconnect wiring on the wafer surface. In further features, said isolation structure includes a shallow trench isolation (STI) structure having a surface, wherein the surface of said isolation structure is substantially co-planar to said substrate wafer surface; said isolation structure includes a gate structure and a spacer structure; the diode structure formed by the method is a polysilicon-gate defined diode Lubistor structure; the step of forming a rectifying contact includes forming a Schottky or Schottky-like contact that is a pure metal, a pure metal alloy, or a silicide-to-semiconductor interface; the step of forming a rectifying contact includes forming a Schottky or Schottky-like contact that is substantially near said gate structure to provide reduced electrical resistance relative to a conventional p-n diode structure; the method further includes a step of providing, via the Schottky or Schottky-like contact, reduced electrical capacitance relative to a conventional p-n diode structure; the spacer structure abuts a sidewall of said gate structure, and wherein the method further includes adjusting the electrical coupling to the rectifying contact via the spacer structure; the method further includes a step of modulating a band structure of the Schottky or Schottky-like contact with anneal parameters, and wherein the anneal parameters comprise a temperature and/or a time; the method further includes a step of modulating a band structure of the Schottky or Schottky-like contact by dopant segregation implantation dose and/or dopant segregation implantation energy; the step of forming the rectifying contact includes forming the rectifying contact from a refractory metal, and wherein said refractory metal includes one or more of Co, Ni, Ni/Pt, Pd, Pt, Ta, TaN, Ti, TiN, and W; said well region has a dopant polarity that is the same dopant polarity as the cathode, thereby providing a p+/n−/n+ diode; said well region has a dopant polarity that is the same dopant polarity as the anode, thereby providing a p+/p−/n+ diode; and/or said well region includes a first well region and a second well region, wherein the first well region has a dopant polarity that is the same dopant polarity as the anode, and wherein the second well region has a dopant polarity that is the same dopant polarity as the cathode, thereby providing a p+/p−/n−/n+ diode.

Broadly defined, the present invention according to another aspect involves a method of forming a Schottky Barrier Lubistor structure, including the steps of: providing a silicon on insulator (SOI) wafer that includes a substrate, supporting a buried oxide (BOX) layer and a silicon film above said BOX layer, and defining a wafer surface; forming a well region on or within said SOI wafer; forming a gate dielectric on said SOI wafer; depositing a gate stack, the gate stack at least partially defining a gate structure; patterning said gate stack; forming an anode, of a first dopant polarity, in the SOI wafer; forming a cathode, of a second dopant polarity, in the SOI wafer; and forming a rectifying contact on at least one of the anode region and the cathode region, wherein the rectifying contact is a Schottky or Schottky-like contact formed substantially near the wafer surface.

In a feature related to this aspect, the method further includes a step of forming and patterning a spacer structure adjacent said gate stack.

In another feature related to this aspect, the method further includes a step of patterning and defining inter-level dielectric (ILD) and interconnect wiring.

In a feature related to this aspect, the at least one of the anode region and the cathode region on which the rectifying contact is formed is formed by implanting a dopant segregation implant and forming the dopant segregation implant to provide the Schottky or Schottky-like contact. In a further feature, at least one of the anode and the cathode is formed by implantation.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

Further features, embodiments, and advantages of the present invention will become apparent from the following detailed description with reference to the drawings, wherein:

FIG. 1 is a cross-section of a prior art shallow trench isolation (STI)-defined bulk CMOS p-n diode structure used for ESD protection;

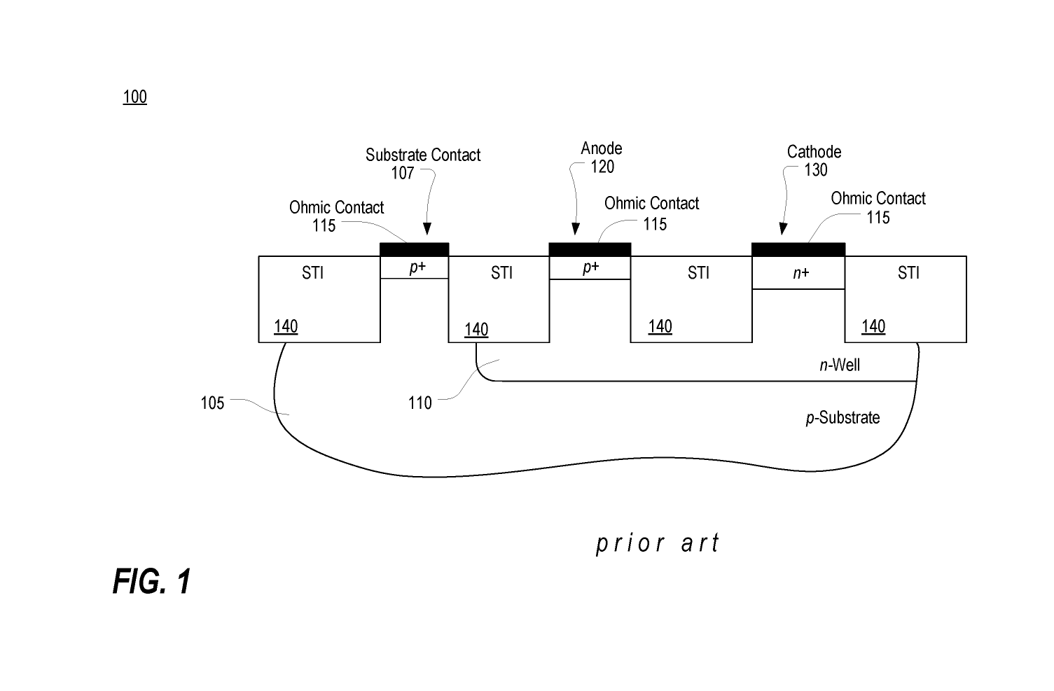

FIG. 2 is a cross-section of a prior art polysilicon gate defined lateral bulk CMOS p-n diode structure used for ESD protection;

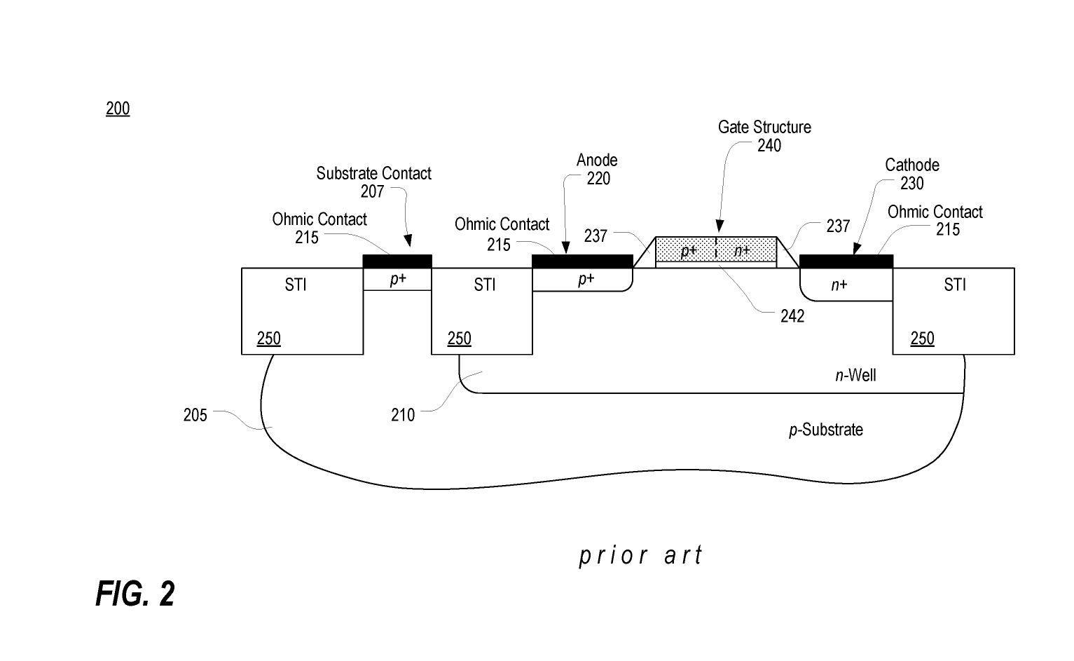

FIG. 3A is a cross-section of a Shallow Trench Isolation Schottky Barrier diode (STISBD) structure in accordance with one or more first preferred embodiments of the present invention;

FIG. 3B is a cross-section of an alternative Shallow Trench Isolation Schottky Barrier diode (STISBD) structure using an approach similar to that of FIG. 3A;

FIG. 4A is a cross-section of a p+/n−/n+ Schottky Barrier Lubistor structure in accordance with one or more second preferred embodiments of the present invention;

FIG. 4B is a cross-section of a p+/p−/n+ Schottky Barrier Lubistor structure in accordance with one or more third preferred embodiments of the present invention;

FIG. 4C is a cross-section of a p+/p−/n−/n+ Schottky Barrier Lubistor structure in accordance with one or more fourth preferred embodiments of the present invention;

FIG. 5A is a cross-section of a p+/n−/n+ silicon on insulator (SOI) Schottky Barrier Lubistor structure in accordance with one or more fifth preferred embodiments of the present invention;

FIG. 5B is a cross-section of a p+/p−/n+ silicon on insulator (SOI) Schottky Barrier Lubistor structure in accordance with one or more sixth preferred embodiments of the present invention;

FIG. 5C is a cross-section of a p+/p−/n−/n+ silicon on insulator (SOI) Schottky Barrier Lubistor structure in accordance with one or more seventh preferred embodiments of the present invention;

FIG. 6 is a cross-section of a p+/p−/n+ Schottky Barrier Lubistor structure with shallow trench isolation (STI) adjacent to the cathode in accordance with one or more eighth preferred embodiments of the present invention;

FIG. 7A is a cross-section of a silicon on insulator Dynamic Threshold Schottky Barrier MOS (DTSBMOS) structure with Schottky source in accordance with one or more ninth preferred embodiments of the present invention;

FIG. 7B is a cross-section of a silicon on insulator Dynamic Threshold Schottky Barrier MOS (DTSBMOS) structure with Schottky drain in accordance with one or more tenth preferred embodiments of the present invention;

FIG. 8A is a cross-section of a silicon on insulator diode-configured Dynamic Threshold Schottky Barrier MOS (DTSBMOS) structure with a Schottky drain in accordance with one or more eleventh preferred embodiments of the present invention;

FIG. 8B is a cross-section of a silicon on insulator diode-configured Dynamic Threshold Schottky Barrier MOS (DTSBMOS) structure with a Schottky drain and Schottky source in accordance with one or more twelfth preferred embodiments of the present invention;

FIG. 9 is a flowchart illustrating a method of forming a STI Schottky Barrier diode (STISBD) structure in accordance with one or more preferred embodiments of the present invention;

FIG. 10 is a flowchart illustrating a method of forming a p−/n−/n+ Schottky Barrier Lubistor structure in accordance with one or more preferred embodiments of the present invention; and

FIG. 11 is a flowchart illustrating a method of forming a diode-configured silicon on insulator Dynamic Threshold Schottky Barrier MOS (DTSBMOS) structure with a Schottky drain and Schottky source in accordance with one or more preferred embodiments of the present invention.

### DETAILED DESCRIPTION OF THE PREFERRED EMBODIMENTS

As a preliminary matter, it will readily be understood by one having ordinary skill in the relevant art (“Ordinary Artisan”) that the present invention has broad utility and application. Furthermore, any embodiment discussed and identified as being “preferred” is considered to be part of a best mode contemplated for carrying out the present invention. Other embodiments also may be discussed for additional illustrative purposes in providing a full and enabling disclosure of the present invention. Moreover, many embodiments, such as adaptations, variations, modifications, and equivalent arrangements, will be implicitly disclosed by the embodiments described herein and fall within the scope of the present invention.

Accordingly, while the present invention is described herein in detail in relation to one or more embodiments, it is to be understood that this disclosure is illustrative and exemplary of the present invention, and is made merely for the purposes of providing a full and enabling disclosure of the present invention. The detailed disclosure herein of one or more embodiments is not intended, nor is to be construed, to limit the scope of patent protection afforded the present invention, which scope is to be defined by the claims and the equivalents thereof. It is not intended that the scope of patent protection afforded the present invention be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection afforded the present invention is to be defined by the appended claims rather than the description set forth herein.

Additionally, it is important to note that each term used herein refers to that which the Ordinary Artisan would understand such term to mean based on the contextual use of such term herein. To the extent that the meaning of a term used herein—as understood by the Ordinary Artisan based on the contextual use of such term—differs in any way from any particular dictionary definition of such term, it is intended that the meaning of the term as understood by the Ordinary Artisan should prevail.

Furthermore, it is important to note that, as used herein, “a” and “an” each generally denotes “at least one,” but does not exclude a plurality unless the contextual use dictates otherwise. Thus, reference to “a picnic basket having an apple” describes “a picnic basket having at least one apple” as well as “a picnic basket having apples.” In contrast, reference to “a picnic basket having a single apple” describes “a picnic basket having only one apple.”

When used herein to join a list of items, “or” denotes “at least one of the items,” but does not exclude a plurality of items of the list. Thus, reference to “a picnic basket having cheese or crackers” describes “a picnic basket having cheese without crackers”, “a picnic basket having crackers without cheese”, and “a picnic basket having both cheese and crackers.” Finally, when used herein to join a list of items, “and” denotes “all of the items of the list.” Thus, reference to “a picnic basket having cheese and crackers” describes “a picnic basket having cheese, wherein the picnic basket further has crackers,” as well as describes “a picnic basket having crackers, wherein the picnic basket further has cheese.”

Referring now to the drawings, in which like numerals represent like components throughout the several views, the preferred embodiments of the present invention are next described. The following description of the preferred embodiment(s) is merely exemplary in nature and is in no way intended to limit the invention, its application, or uses.

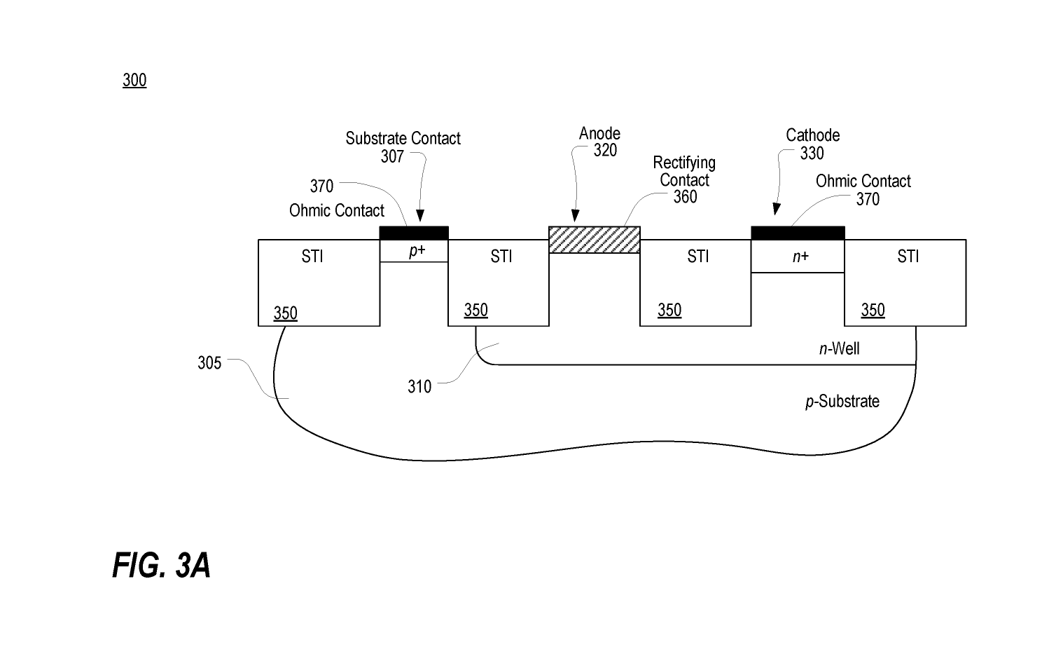

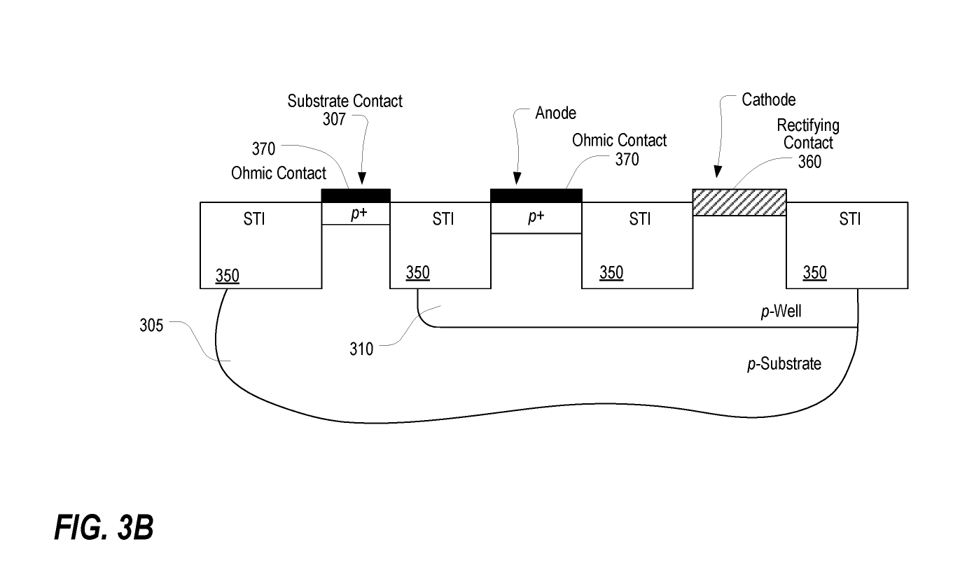

FIG. 3A is a cross-section of a Shallow Trench Isolation Schottky Barrier diode (STISBD) structure 300 in accordance with one or more first preferred embodiments of the present invention. The structure 300 contains a p-Substrate wafer 305 and an n-Well region 310. The structure 300 further includes an anode 320 and a cathode 330, which are defined by shallow trench isolation (STI) structures 350. The n+ implant is the implant used to define an n+ MOSFET source/drain implant. An ohmic contact region 370 is formed on the n+ cathode 330 using standard metallization techniques. A rectifying contact 360 forms the anode 320. A substrate contact 307 with an ohmic contact region 370 is also provided to electrically connect to the substrate 305. Metallization layers and interlevel dielectric (ILD) are placed on the wafer surface.

Notably, although shown with a p-Substrate wafer 305, an n-Well region 310, a rectifying contact anode 320, and an n+ cathode 330, it will be appreciated that a Shallow Trench Isolation Schottky Barrier diode structure may alternatively be established using a p-Well region, a p+ anode implant, and a rectifying contact cathode, where an ohmic contact region is formed on the p+ anode, and a Schottky or Schottky-like contact forms the cathode. Such a structure is shown in FIG. 3B.

The rectifying contact 360 can be formed by a Schottky or Schottky-like contact from a variety of techniques, including pure metal deposition, silicide deposition including deposition and annealing, dopant segregation or novel contact techniques. As used herein, a Schottky contact or Schottky-like contact is intended to mean a conducting layer (e.g., metal, pure metal, metal alloy, pure metal alloy, silicide, and other conducting materials) formed on a semiconductor substrate to define a “rectifying barrier junction” between the conducting layer and the semiconductor substrate. A Schottky contact is defined as a rectifying barrier junction between a metal layer (e.g., pure metal or alloy) and a semiconductor substrate. A Schottky-like contact is defined as a rectifying barrier junction between a metal conducting layer and a semiconductor substrate or a non-metal and metal conducting layer and a semiconductor substrate, where the band structure, including the barrier height, of the junction can be modulated. As used herein, modulate refers to a technique that modifies the band structure (e.g., barrier height, shape, profile steepness, electrical conductivity, etc.) between the conducting layer and the semiconductor substrate, such as by specifying the conducting layer material (e.g., metal, metal alloy, silicide, and other conducting materials), dopant segregation, other techniques described herein, and/or other techniques known to one of ordinary skill in the art. As used herein, a non-metal and metal conducting layer refers to a conducting layer that includes metal elements and non-metal elements. In a preferred embodiment, the non-metal and metal conducting layer is a metal silicide conducting layer, resulting in an interfacial dopant segregation layer and corresponding depletion region. Since embodiments of the invention do not include an n+ region, the parasitic n-p-n transistor and its associated undesirable effects are eliminated.

Structurally, the Schottky-like contact can be regarded as a first and second film, where the first film is a silicide film, and a second film which is an interfacial dopant segregation layer. The Schottky-like contact is formed substantially near the surface of said substrate comprising a silicide layer and an interfacial dopant segregation layer, wherein said interfacial dopant segregation layer provides electrical coupling to the conducting layer of the rectifying contact.

By way of example and not limitation, the Schottky-like contact may, in at least some embodiments, be formed using the so-called Silicidation-Induced Dopant Segregation (SIDS) technique. The band structure can be modulated via anneal parameters (e.g., anneal temperature and anneal time) or dopant segregation implant parameters (e.g., dopant segregation implantation dose and dopant segregation energy). For an n-type cathode of the diode device, before a source/drain silicide is formed, the silicon surface is arsenic implanted (dopant segregation implant), at a dose, for example, of 10¹⁵ cm⁻³. For a p-type anode of the diode device, before a source/drain silicide is formed, the silicon surface is boron implanted. Immediately following the implant, without annealing, the silicide metal is deposited using, for example Co, Ni, Ni/Pt, Pd, Pt, Ta, TaN, Ti, TiN or W. Silicide formation takes place via a following anneal, a single-step anneal or a multi-step anneal involving both formation and conversion steps.

The anneal has the dual effect of generating the desired silicide stoichiometry as well as redistributing the dopant ahead of the silicide/silicon interface to form a very thin interface region at the edge of the source/drain silicide. Another technique for forming the rectifying contact 360 is to use an appropriately valued work function metal or metal alloy, without requiring the use of a SIDS technique. In either case, the most important attribute of the structure is that a rectifying barrier junction is formed at the source and/or drain to channel junction, at what is normally a p-n junction interface. As the refractory metal consumes the silicon atoms during silicidation, the implant dopants are redistributed, resulting in a steeper, modified impurity profile than that seen in conventional diffused profiles. This highly-doped region of impurities is used to modulate the band structure between the amorphous silicide and the single-crystal silicon. It is desirable for the barrier height to be minimized for ESD protection structures, especially for use in high data rate circuits (e.g., LVDS, serial interfaces, input/output elements) and RF components.

Experimental results also demonstrate that the band structure of the rectifying barrier junction can be modulated by the anneal temperatures in the temperature ranges of 400 to 800 degrees C. The band structure can also be modulated by the dopant segregation implantation dose/energy. The depletion region of the rectifying barrier junction may extend past the dopant segregation layer to under the gate region to allow for electrical coupling and reduced series resistance. The electrical coupling can be modulated by the spacer structure, dopant segregation implantation dose/energy, and thermal anneals.

After the gate material is deposited and patterned, a spacer structure is formed to control the distance between the edge of the gate and the edge of the rectifying contact. The spacer structure, formed from SiO₂, SiN or any other convenient insulating material, can be adjusted to provide optimum electrical coupling to the conducting layer of the rectifying contact. After the spacer structure formation, standard photolithography techniques are used to define regions where the p+ body contact is implanted. After the p+ body contact implant and anneal, the rectifying contact is formed. If the transistor has an ohmic contact on the source or drain, the spacer structure can be the same as utilized by other transistors on the semiconductor chip (e.g. the standard MOSFET spacer structure). An asymmetrical spacer structure provides the flexibility to independently establish the appropriate electrical coupling on the source side, independent of the drain side. A disposable spacer technique can be utilized, wherein the spacer structure on the side of the rectifying contact can be removed to improve electrical coupling between the rectifying contact and the gate structure.

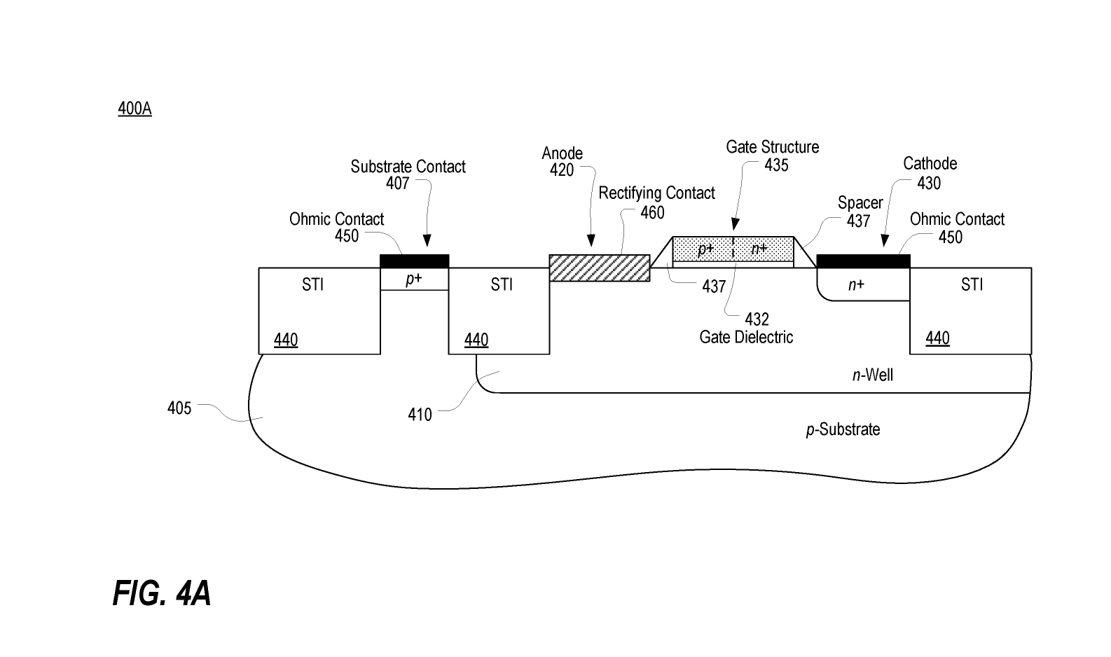

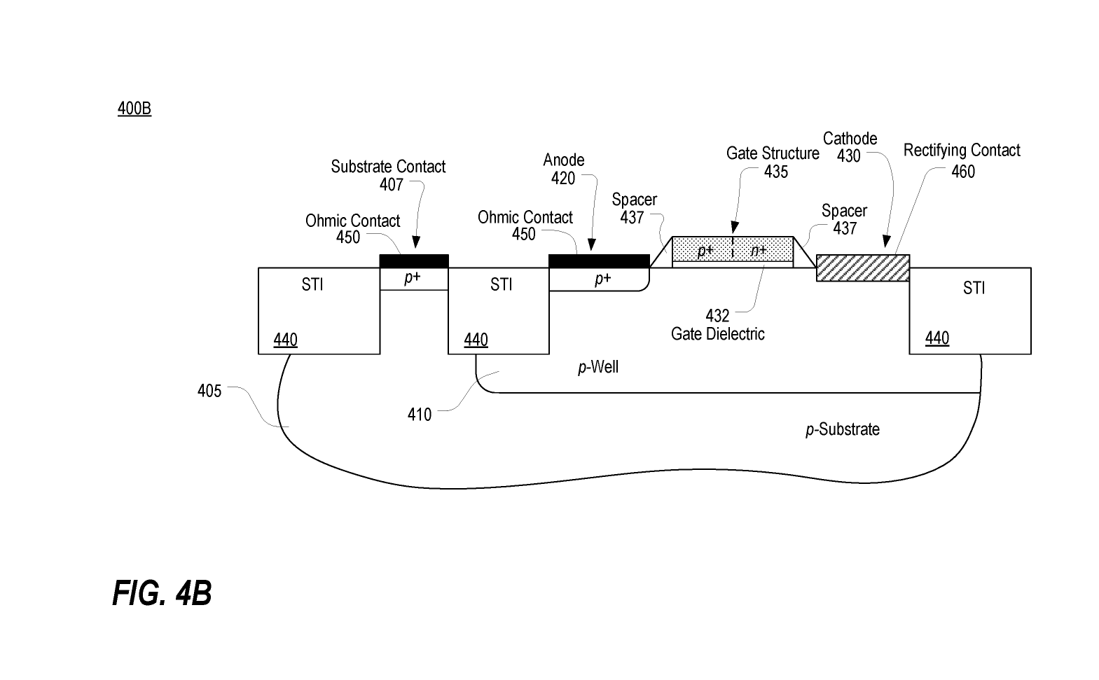

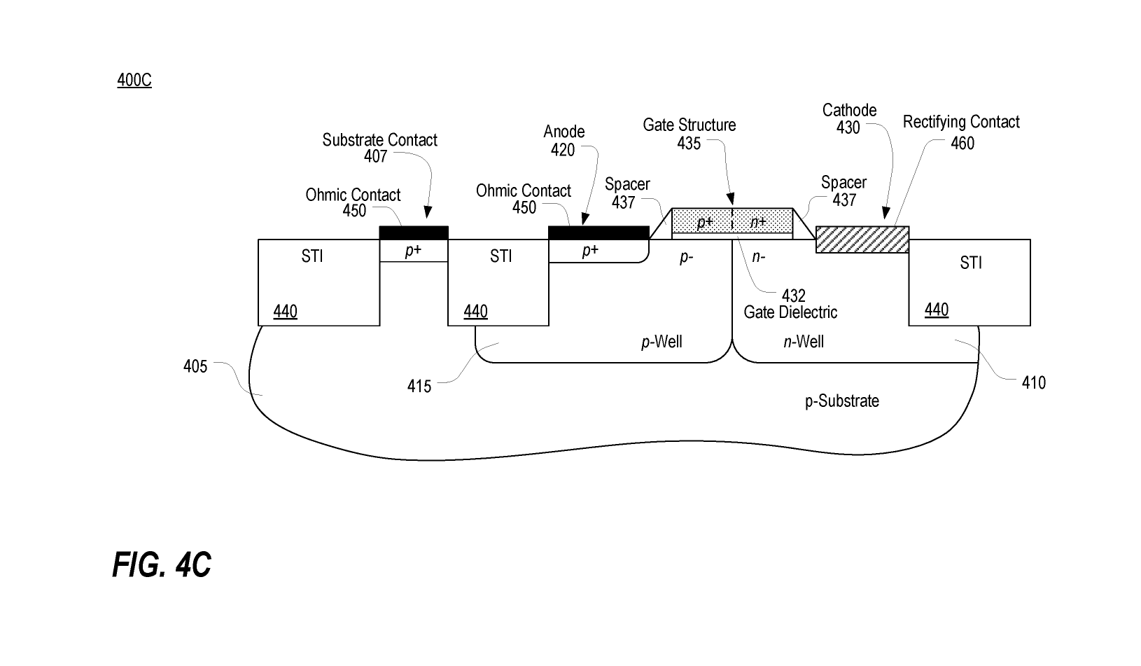

FIG. 4A is a cross-section of a p+/n−/n+ Schottky Barrier Lubistor structure 400A in accordance with one or more second preferred embodiments of the present invention. The structure 400A contains a p-Substrate wafer 405 and an n-Well region 410. The structure further includes an anode 420, and an n+ region forming a cathode 430. A thin gate oxide or other gate dielectric layer 432 is formed on top of the n-Well 410, and the well is partially covered by a gate structure 435. Spacer structures 437 are located on the sidewalls of the gate structure 435. The anode 420 and n+ cathode 430 are defined by the gate structure 435 and spacers 437. On the perimeter, the anode 420 and n+ cathode 430 are defined by shallow trench isolation (STI) structures 440. An ohmic contact region 450 is formed on the n+ cathode 430 using standard metallization techniques. A rectifying contact 460 forms the anode 420. A substrate contact 407 with an ohmic contact region 450 is also provided to electrically connect to the substrate 405 with STI regions 440 isolating the ohmic contact region 450 of the substrate contact 407. Metallization layers and interlevel dielectric (ILD) are placed on the wafer surface.

It will be appreciated that a structure corresponding to the structure 400A of FIG. 4A can be established using a p+ anode implant, a p-Well region, and a cathode, where the p+ region is implanted and an ohmic contact region is formed, and the cathode is formed with a rectifying contact 460. In this regard, FIG. 4B is a cross-section of a p+/p−/n+ Schottky Barrier Lubistor structure 400B in accordance with one or more third preferred embodiments of the present invention. The structure 400B contains a p-Substrate wafer 405 and a p-Well region 410. The structure further includes a p+ region forming an anode 420 and a cathode 430. A thin gate oxide or other gate dielectric layer 432 is formed on top of the p-Well 410, and the well is partially covered by a gate structure 435. Spacer structures 437 are located on the sidewalls of the gate structure 435. The p+ anode 420 and cathode 430 are defined by the gate structure 435 and spacers 437. On the perimeter, the p+ anode 420 and cathode 430 are defined by shallow trench isolation (STI) structures 440. An ohmic contact region 450 is formed on the p+ anode 420 using standard metallization techniques. A rectifying contact 460 forms on the cathode 430. A substrate contact 407 with an ohmic contact region 450 is also provided to electrically connect to the substrate 405 with STI regions 440 isolating the ohmic contact region 450 of the substrate contact 407. Metallization layers and interlevel dielectric (ILD) are placed on the wafer surface.

FIG. 4C is a cross-section of a p+/p−/n−/n+ Schottky Barrier Lubistor structure 400C in accordance with one or more fourth preferred embodiments of the present invention. Like the structures 400A, 400B of FIGS. 4A and 4B, the structure 400C includes a p-Substrate wafer 405 and a well region, but in this embodiment, the “dual well” region under the gate structure has both a p-Well region 415 and an n-Well region 410, with the n-Well/p-Well junction being centered under the gate structure. The “dual well” junction can be realized by layout design, without an extra mask layer or process step. The structure further comprises a p+ region forming an anode 420 and a cathode 430. A thin gate oxide or other gate dielectric layer 432 is formed on top of the n-Well 410 and p-Well 415, and the wells are partially covered by a gate structure 435. Spacer structures 437 are located on the sidewalls of the gate structure 435. The p+ anode 420 and cathode 430 are defined by the gate structure 435 and spacers 437. On the perimeter, the p+ anode 420 and cathode 430 are defined by shallow trench isolation (STI) structures 440. An ohmic contact region 450 is formed on the p+ anode 420 using standard metallization techniques. A rectifying contact 460 forms the cathode 430. A substrate contact 407 with an ohmic contact region 450 is also provided to electrically connect to the substrate 405 with STI regions 440 isolating the ohmic contact region 450 of the substrate contact 407. Metallization layers and interlevel dielectric (ILD) are placed on the wafer surface.

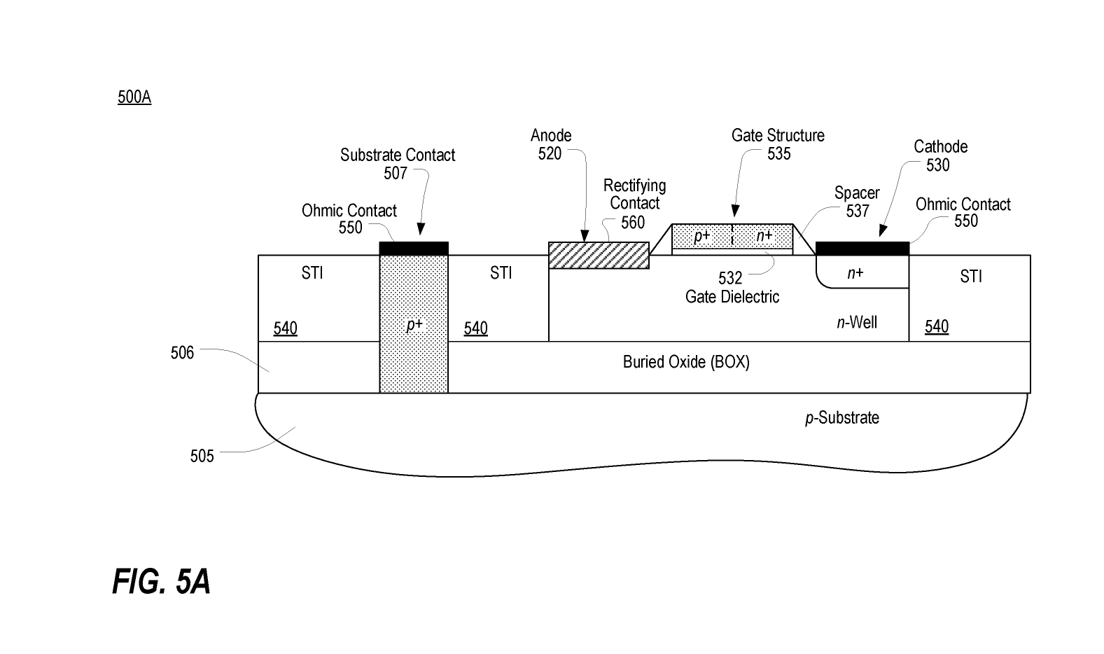

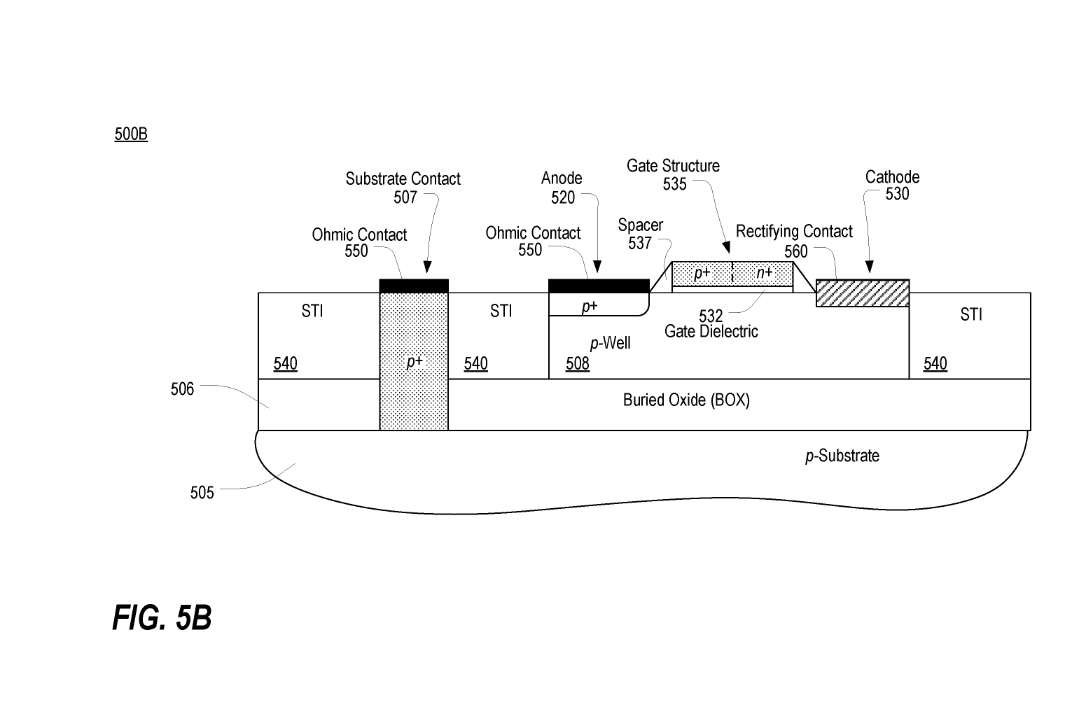

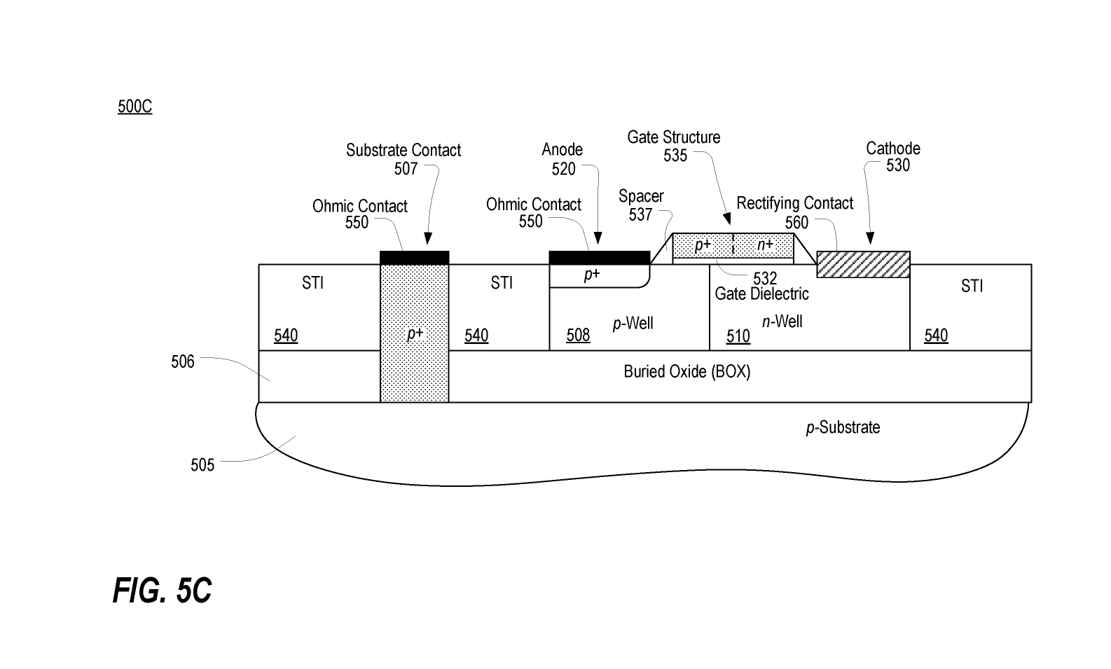

FIG. 5A is a cross-section of a p+/n−/n+ silicon on insulator (SOI) Schottky Barrier Lubistor structure 500A in accordance with one or more fifth preferred embodiments of the present invention. The structure 500A includes a p-Substrate wafer 505, a buried oxide (BOX) layer 506, and an n-Well region 510. A p-Well region (not shown) may be used for other devices on the wafer substrate. The structure further includes an anode 520 and an n+ region forming a cathode 530. A thin gate oxide or other gate dielectric layer 532 is formed on top of the n-Well 510, and the well is partially covered by a gate structure 535. Spacer structures 537 are located on the sidewalls of the gate structure 535. The anode 520 and n+ cathode 530 are defined by the gate structure 535 and spacer 537. On the perimeter, the anode 520 and n+ cathode 530 are defined by shallow trench isolation (STI) structures 540. An ohmic contact region 550 is formed on the n+ cathode 530 using standard metallization techniques. A rectifying contact 560 forms the anode 520. A substrate contact 507 with an ohmic contact region 550 is also provided to electrically connect to the substrate 505 with STI regions 540 isolating the ohmic contact region 550 of the substrate contact 507. Metallization layers and interlevel dielectric (ILD) are placed on the wafer surface.

FIG. 5B is a cross-section of a p+/p−/n+ silicon on insulator (SOI) Schottky Barrier Lubistor structure 500B in accordance with one or more sixth preferred embodiments of the present invention. The structure 500B includes a p-Substrate wafer 505, a buried oxide (BOX) layer 506, and a p-Well layer 508. An n-Well region (not shown) may be used for other devices on the wafer substrate. The structure further comprises a p+ region forming an anode 520 and a cathode 530. A thin gate oxide or other gate dielectric layer 532 is formed on top of the p-Well 508, and the well is partially covered by a gate structure 535 typically formed from n+ polysilicon. Spacer structures 537 are located on the sidewalls of the gate structure 535. The p+ anode 520 and cathode 530 are defined by the gate structure 535 and spacer 537. On the perimeter, the p+ anode 520 and cathode 530 are defined by shallow trench isolation (STI) structures 540. An ohmic contact region 550 is formed on the p+ anode 520 using standard metallization techniques. A rectifying contact 560 forms the cathode 530. A substrate contact 507 with an ohmic contact region 550 is also provided to electrically connect to the substrate 505 with STI regions 540 isolating the ohmic contact region 550 of the substrate contact 507. Metallization layers and interlevel dielectric (ILD) are placed on the wafer surface.

FIG. 5C is a cross-section of a p+/p−/n−/n+ silicon on insulator (SOI) Schottky Barrier Lubistor structure 500C in accordance with one or more seventh preferred embodiments of the present invention. The structure 500C includes a p-Substrate wafer 505, a buried oxide (BOX) layer 506, a p-Well layer 508, and an n-Well region 510. The “dual well” region under the gate structure has both a p-Well region 508 and an n-Well region 510, with the n-Well/p-Well junction being centered under the gate structure. The “dual well” junction can be realized by layout design, without an extra mask layer or process step. The structure further comprises a p+ region forming an anode 520, and a cathode 530. A thin gate oxide or other gate dielectric layer 532 is formed on top of the p-Well 508 and n-Well 510, and the wells are partially covered by a gate structure 535. The gate structure 535 has a spacer structure 537 on the sidewalls. The p+ anode 520 and cathode 530 are defined by the gate structure 535 and spacer 537. On the perimeter, the p+ anode 520 and cathode 530 are defined by shallow trench isolation (STI) structures 540. An ohmic contact region 550 is formed on the p+ anode 520 using standard metallization techniques. A rectifying contact 560 forms the cathode 530. A substrate contact 507 with an ohmic contact region 550 is also provided to electrically connect to the substrate 505 with STI regions 540 isolating the ohmic contact region 550 of the substrate contact 507. Metallization layers and interlevel dielectric (ILD) are placed on the wafer surface.

In the SOI technology, the shallow trench isolation 540 can abut the buried oxide (BOX) layer 506 isolating the p-Well 508 and/or n-Well region 510. In partially-depleted SOI, the doped region for the anode 520 or cathode 530 can be above the depth of the buried oxide (BOX) layer 506. In fully-depleted SOI technology, the implants are extended to the buried oxide (BOX) layer 506. In at least some embodiments, the region (e.g. anode or cathode) which has the ohmic contact 550 extends to the buried oxide (BOX) layer, whereas the rectifying contact 560 does not. In embodiments where the anode and cathode are both rectifying contacts, the device can be scaled to thin the silicon film for ultra-thin SOI (UTSOI) applications.

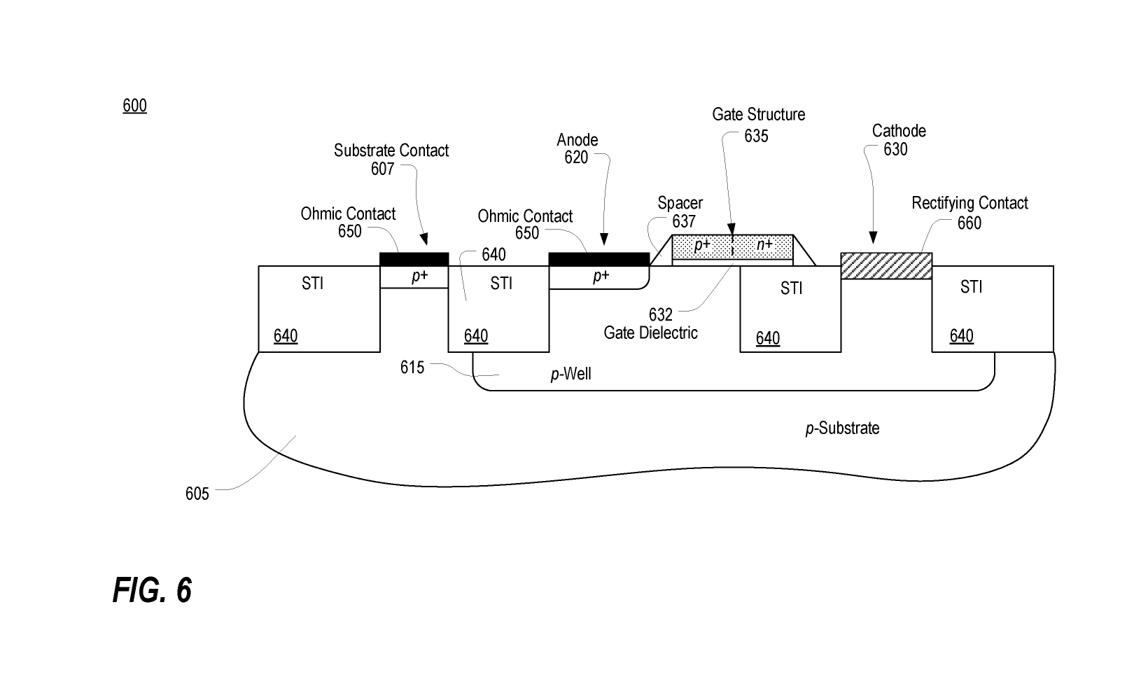

FIG. 6 is a cross-section of a p+/p−/n+ Schottky Barrier Lubistor structure 600 with shallow trench isolation (STI) structures adjacent to the cathode 630 in accordance with one or more eighth preferred embodiments of the present invention. The structure 600 includes a p-Substrate wafer 605 and a p-Well region 615. The structure further comprises a p+ region forming an anode 620 and a cathode 630. A thin gate oxide or other gate dielectric layer 632 is formed on top of the p-Well 615, and the well is partially covered by a gate structure 635. The gate structure 635 has a spacer structure 637 on the sidewalls. The p+ anode 620 is defined by the gate structure 635 and spacer 637, while the cathode 630 is defined by a shallow trench isolation (STI) structure 640 over which the gate structure 635 extends. On the perimeter, the p+ anode 620 and cathode 630 are defined by further shallow trench isolation (STI) structures 640. An ohmic contact region 650 is formed on the p+ anode 620 using standard metallization techniques. A rectifying contact 660 forms the cathode 630. A substrate contact 607 with an ohmic contact region 650 also exists to electrically connect to the substrate 605. Metallization layers and interlevel dielectric (ILD) are placed on the wafer surface.

Although not illustrated, it will be appreciated that a corresponding p+/n−/n+ Schottky Barrier Lubistor Structure with shallow trench isolation (STI) structures adjacent to the anode 620 may alternatively be formed using a similar approach. More particularly, a rectifying contact 660 may be formed on the anode 620 and the gate structure 635 may be formed on top of an n-Well to create a p+/n−/n+ Schottky Barrier Lubistor Structure. Furthermore, in some embodiments, a dual well approach is utilized, wherein p-Wells and n-Wells are used on the same substrate and both of the foregoing types of structures are formed. In addition, the Schottky Barrier Lubistor structure with STI may alternatively be formed on SOI substrates.

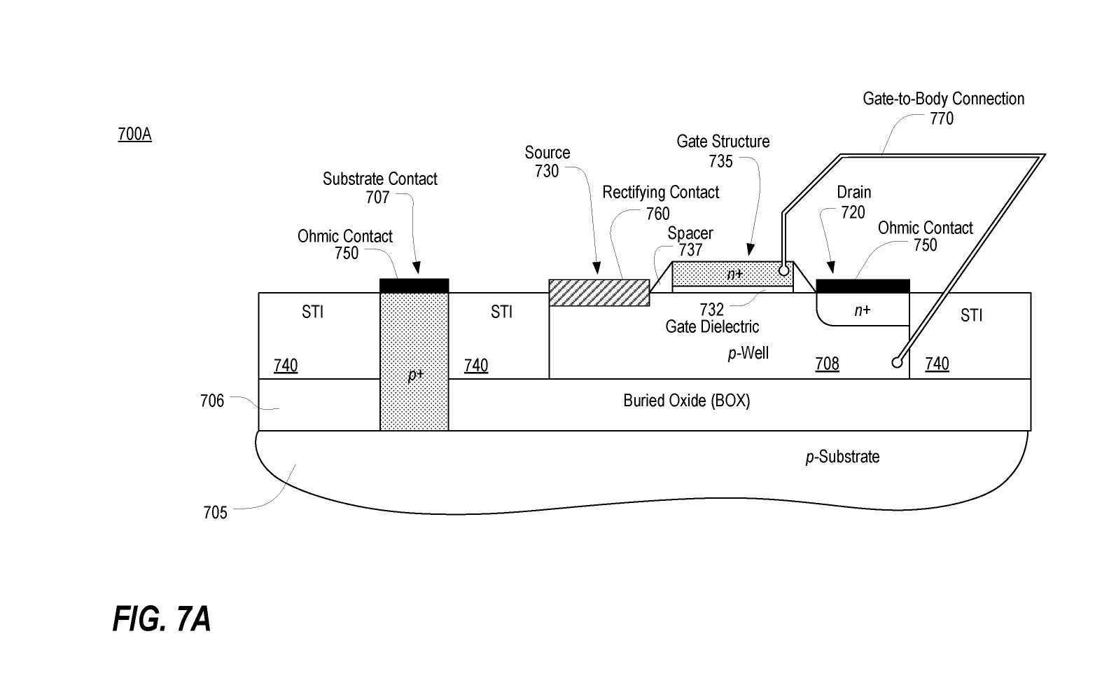

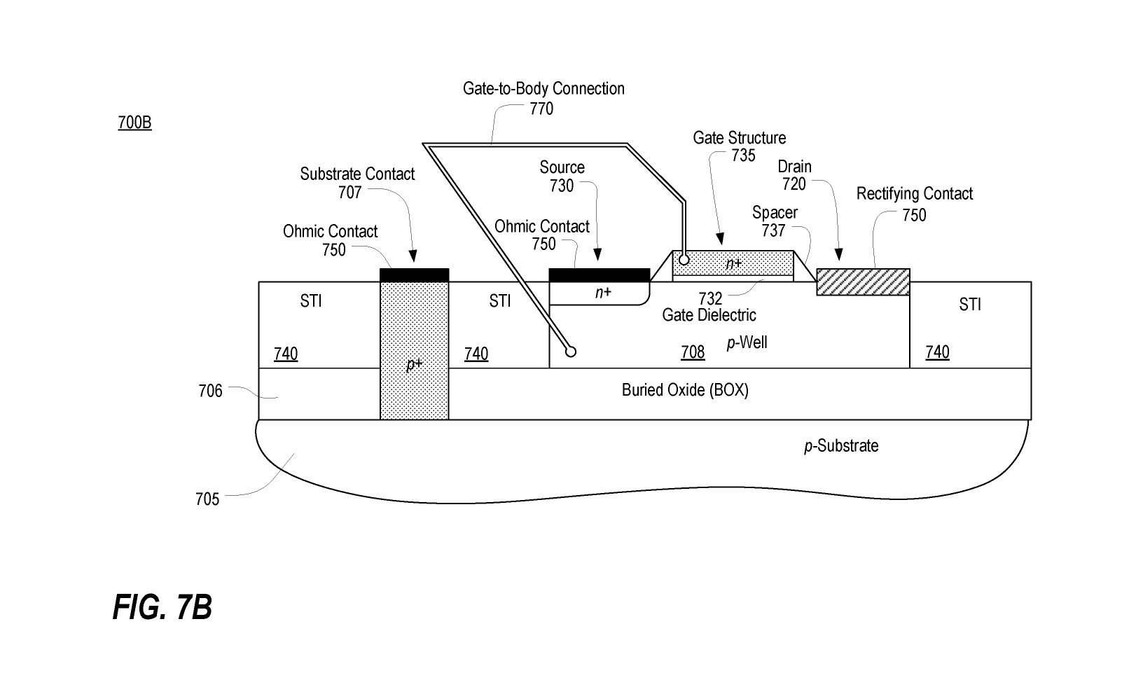

FIG. 7A is a cross-section of a Dynamic Threshold Schottky Barrier MOS (DTSBMOS) structure 700A with a Schottky or Schottky-like contact at the source in accordance with one or more ninth preferred embodiments of the present invention. The DTSBMOS structure 700A operates as a type of dynamic threshold-voltage MOS (DTMOS) device, wherein a connection 770 couples the body and the gate of the MOSFET together. The structure 700A includes a p-Substrate wafer 705, a buried oxide (BOX) layer 706, and a p-Well layer 708. The p-Well 708 serves as the body of the DTMOS device which is coupled to the MOSFET gate. The structure 700A further includes an n+ region, forming a drain 720, and a source 730. A thin gate oxide or other gate dielectric layer 732 is formed on top of the p-Well 708, and the well is partially covered by a gate structure 735, which in at least some embodiments is a MOSFET. Spacer structures 737 are located on the sidewalls of the MOSFET gate structure 735. The source 730 and drain 720 of the MOSFET are defined by the gate structure 735 and spacer 737. On the perimeter, the source 730 and drain 720 are defined by shallow trench isolation (STI) structures 740. An ohmic contact region 750 is formed on the drain 720 using standard metallization techniques. A rectifying contact 760 forms the MOSFET source 730. Notably, the spacer structure 737 can be adjusted to provide optimum electrical coupling to the conducting layer of the rectifying contact 760. The regions of the rectifying contact 760 and the body may be self-aligned (or non-self-aligned) to a common photolithographic feature or can be defined by separate photolithographic features. A substrate contact 707 with an ohmic contact region 750 is also provided to electrically connect to the substrate 705 with STI regions 740 isolating the ohmic contact region 750 of the substrate contact 707. Metallization layers and interlevel dielectric (ILD) are placed on the transistor structure.

FIG. 7B is a cross-section of a Dynamic Threshold Schottky Barrier MOS (DTSBMOS) structure 700B with Schottky or Schottky-like contact at the drain in accordance with one or more tenth preferred embodiments of the present invention. As with the structure 700A of FIG. 7A, the DTSBMOS structure 700B of FIG. 7B is a type of dynamic threshold-voltage MOS (DTMOS) device, wherein a connection 770 couples the body and the gate of the MOSFET together. The structure 700B includes a p-Substrate wafer 705, a buried oxide (BOX) layer 706, and a p-Well region 708. The p-Well 708 serves as the body of the DTMOS device which is coupled to the MOSFET gate 735. The structure 700B further includes a drain 720 and an n+ region forming a source 730. A thin gate oxide or other gate dielectric layer 732 is formed on top of the p-Well 708, and the well is partially covered by a gate structure 735, which in at least some embodiments is a MOSFET, and is shown in FIG. 7A and 7B as an n-type MOSFET. Spacer structures 737 are located on the sidewalls of the MOSFET gate structure 735. The source 730 and drain 720 of the MOSFET are defined by the gate structure 735 and spacer 737. On the perimeter, the source 730 and drain 720 of the MOSFET is defined by shallow trench isolation (STI) structures 740. An ohmic contact region 750 is formed on the source 730 using standard metallization techniques. A rectifying contact 760 forms the MOSFET drain 720. Notably, the spacer structure 737 can be adjusted to provide optimum electrical coupling to the conducting layer of the rectifying contact 760. The regions of the rectifying contact 760 and the body may be self-aligned (or non-self-aligned) to a common photolithographic feature or can be defined by separate photolithographic features. A substrate contact 707 with an ohmic contact region 750 is also provided to electrically connect to the substrate 705 with STI regions 740 isolating the ohmic contact region 750 of the substrate contact 707. Metallization layers and interlevel dielectric (ILD) are placed on the wafer surface.

Although not illustrated, it will be appreciated that a corresponding DTSBMOS may be formed utilizing an n-Well and creating a corresponding p-type MOSFET with the corresponding source and drain regions, and the gate region is also a p+ region. Furthermore, in some embodiments, a dual well approach is utilized, wherein p-Wells and n-Wells are used on the same substrate and both of the foregoing types of structures are formed.

In at least some embodiments, a DTSBMOS structure 700A, 700B is implemented in SOI technology, wherein the shallow trench isolation 740 can abut the buried oxide (BOX) layer 706 isolating the p-Well 708 and/or n-Well region. In partially-depleted SOI, the doped region for the MOSFET source 730 and/or drain 720 can be above the depth of the buried oxide (BOX) layer 706. In fully-depleted SOI technology, the implants are extended to the buried oxide (BOX) layer 706. In at least some embodiments, the MOS ohmic contact 750 extends to the buried oxide (BOX) layer 706, whereas the rectifying contact 760 does not. In embodiments where the source 730 and drain 720 are both rectifying contacts, the device can be scaled to thin the silicon film for ultra-thin SOI (UTSOI) applications.

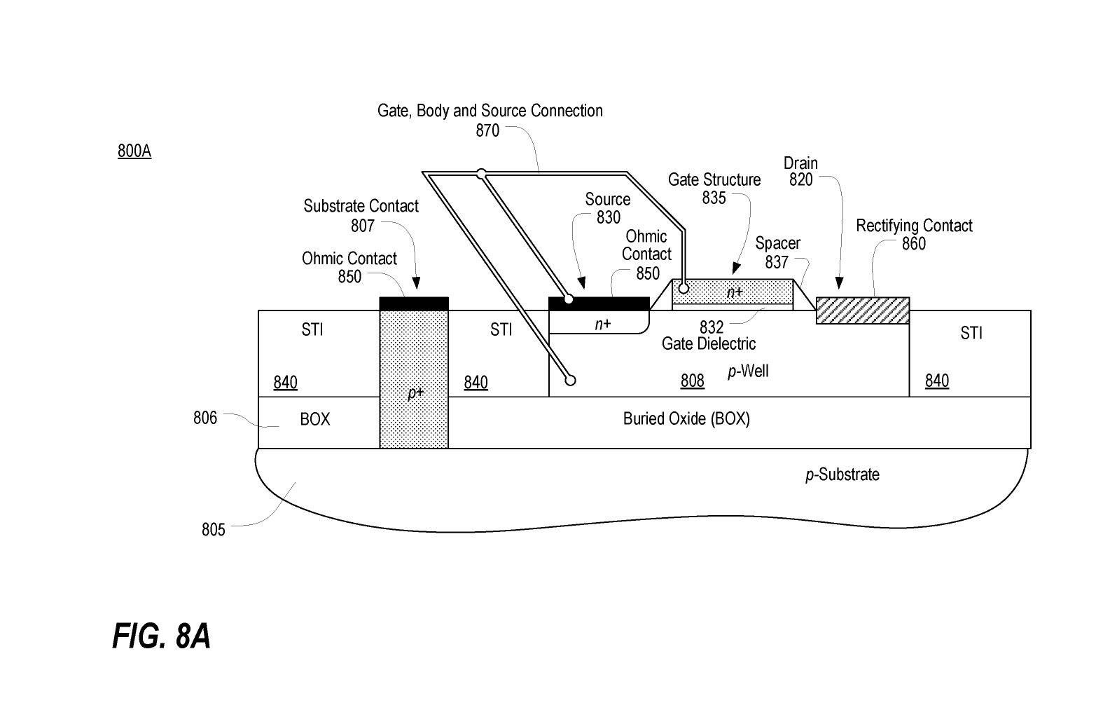

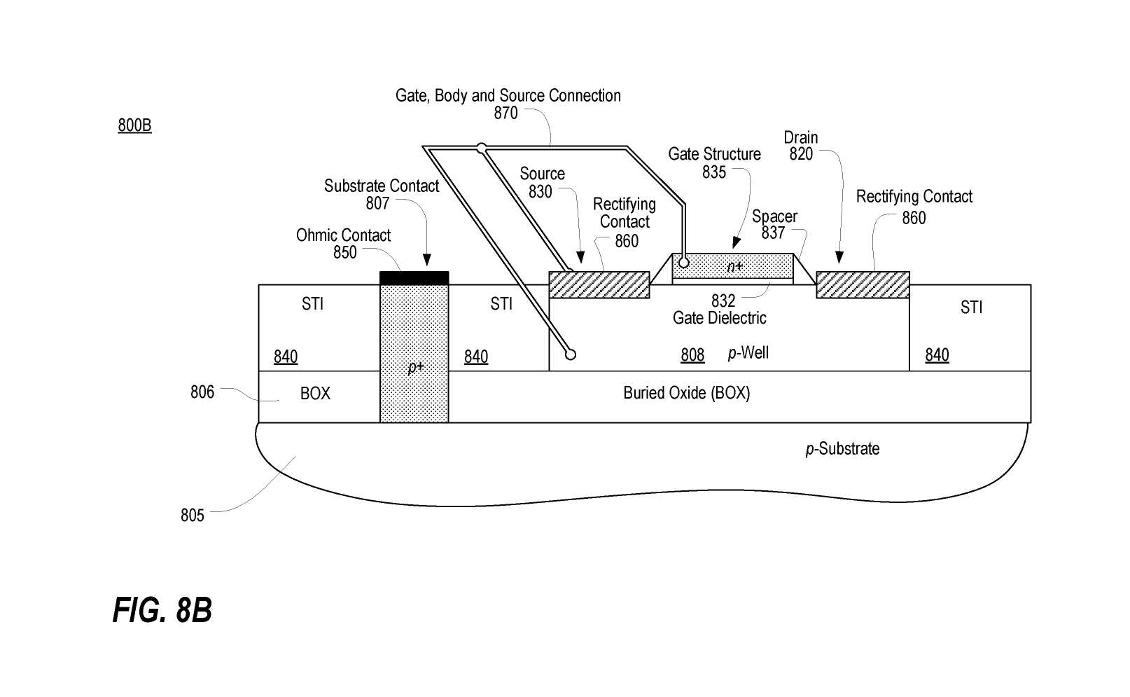

FIG. 8A is a cross-section of a Dynamic Threshold Schottky Barrier MOS (DTSBMOS) diode structure 800A with a Schottky or Schottky-like contact at the drain in accordance with one or more eleventh preferred embodiments of the present invention. The DTSBMOS structure 800A operates as a type of dynamic threshold-voltage MOS (DTMOS) device, wherein a connection 870 couples the body, the gate, and the source of the MOSFET together. The structure 800A includes a p-Substrate wafer 805, a buried oxide (BOX) layer 806, and a p-Well layer 808. The p-Well 808 serves as the body of the DTMOS device which is coupled to the MOSFET gate. The structure 800A further includes a drain 820, and n+ region forming a source 830. A thin gate oxide or other gate dielectric layer 832 is formed on top of the p-Well 808, and the well is partially covered by a gate structure 835, which in at least some embodiments is a MOSFET. Spacer structures 837 are located on the sidewalls of the MOSFET gate structure 835. The source 830 and drain 820 of the MOSFET are defined by the gate structure 835 and spacer 837. On the perimeter, the source 830 and drain 820 are defined by shallow trench isolation (STI) structures 840. An ohmic contact region 850 is formed on the source 830 using standard metallization techniques. A rectifying contact 860 forms the MOSFET drain 820. Notably, the spacer structure 837 can be adjusted to provide optimum electrical coupling to the conducting layer of the rectifying contact 860. The regions of the rectifying contact 860 and the body may be self-aligned (or non-self aligned) to a common photolithographic feature or can be defined by separate photolithographic features. A substrate contact 807 with an ohmic contact region 850 is also provided to electrically connect to the substrate 805 with STI regions 840 isolating the ohmic contact region 850 of the substrate contact 807. Metallization layers and interlevel dielectric (ILD) are placed on the wafer surface.

FIG. 8B is a cross-section of a Dynamic Threshold Schottky Barrier MOS (DTSBMOS) diode structure 800B with Schottky or Schottky-like contacts at both the MOS drain and the MOS source in accordance with one or more twelfth preferred embodiments of the present invention. As with the structure 800A of FIG. 8A, the DTSBMOS structure 800B operates as a type of dynamic threshold-voltage MOS (DTMOS) device, wherein a connection 870 couples the body, the gate, and the source of the MOSFET together. The structure 800B includes a p-Substrate wafer 805, a buried oxide (BOX) layer 806, and a p-Well layer 808. The p-Well 808 serves as the body of the DTMOS device which is coupled to the MOSFET gate. The structure 800B further includes a drain 820 and an n+ region forming a source 830. A thin gate oxide or other gate dielectric layer 832 is formed on top of the p-Well 808, and the well is partially covered by a gate structure 835, which in at least some embodiments is a MOSFET, and is shown in FIG. 8A and 8B as an n-type MOSFET. Spacer structures 837 are located on the sidewalls of the MOSFET gate structure 835. The source 830 and drain 820 of the MOSFET are defined by the gate structure 835 and spacer 837. On the perimeter, the source 830 and drain 820 are defined by shallow trench isolation (STI) structures 840. In FIG. 8B, there are no MOS ohmic contacts; both the MOS source contact 830 and the MOS drain contact 820 are rectifying contacts 860, with a rectifying contact 860 being formed on each of the source 830 and the drain 820 regions. Notably, the spacer structure 837 can be adjusted to provide optimum electrical coupling to the conducting layer of the respective rectifying contact 860. The regions of the rectifying contacts 860 and the body may be self-aligned (or non-self aligned) to common photolithographic features or can be defined by separate photolithographic features. A substrate contact 807 with an ohmic contact region 850 is also provided to electrically connect to the substrate 805 with STI regions 840 isolating the ohmic contact region 850 of the substrate contact 807. Metallization layers and interlevel dielectric (ILD) are placed on the transistor structure.

Although not illustrated, it will be appreciated that a corresponding DTSBMOS diode structure may be formed utilizing an n-Well and creating a corresponding p-type MOSFET with the corresponding source and drain regions, and the gate region is also a p+ region. Furthermore, in some embodiments, a dual well approach is utilized, wherein p-Wells and n-Wells are used on the same substrate and both of the foregoing types of structures are formed.

In at least some embodiments, a DTSBMOS structure 800A, 800B is implemented in SOI technology, wherein the shallow trench isolation 840 can abut the buried oxide (BOX) layer 806 isolating the p-Well 808 and/or n-Well region. In partially-depleted SOI, the doped region for the MOSFET source 830 and/or drain 820 can be above the depth of the buried oxide (BOX) layer 806. In fully-depleted SOI technology, the implants are extended to the buried oxide (BOX) layer 806. In at least some embodiments, the MOS ohmic contact 750 extends to the buried oxide (BOX) layer 706, whereas the rectifying contact 760 does not. In embodiments where the source 830 and drain 820 are both rectifying contacts, the device can be scaled to thin the silicon film (the silicon region above the buried oxide) for ultra-thin SOI (UTSOI) applications.

In each of the DTMOS diode structures 800A,800B of FIGS. 8A and 8B, there are two terminals to the device. The body, gate and source are connected as one terminal, and the drain is the second terminal, forming a “diode” structure with the rectifying barrier junction formed between the p-body and the drain region. In this configuration, the current conduction consists of a DTMOS MOSFET-like conduction between the DTMOS source and drain, and a diode current conduction between the body and the drain region. No electrical stress occurs between the body, the source, and the gate since they are all coupled together. The electrical stress on the drain is the Schottky diode voltage between the p-body anode and the drain cathode. The gate-to-Schottky voltage stress can also be controlled by the spacer structure to adjust the electrical coupling to the rectifying contact. In at least some embodiments, the structure can include a second gate, which would be formed in the buried oxide (BOX) layer 806, providing a dual gate “diode” DTMOS device.

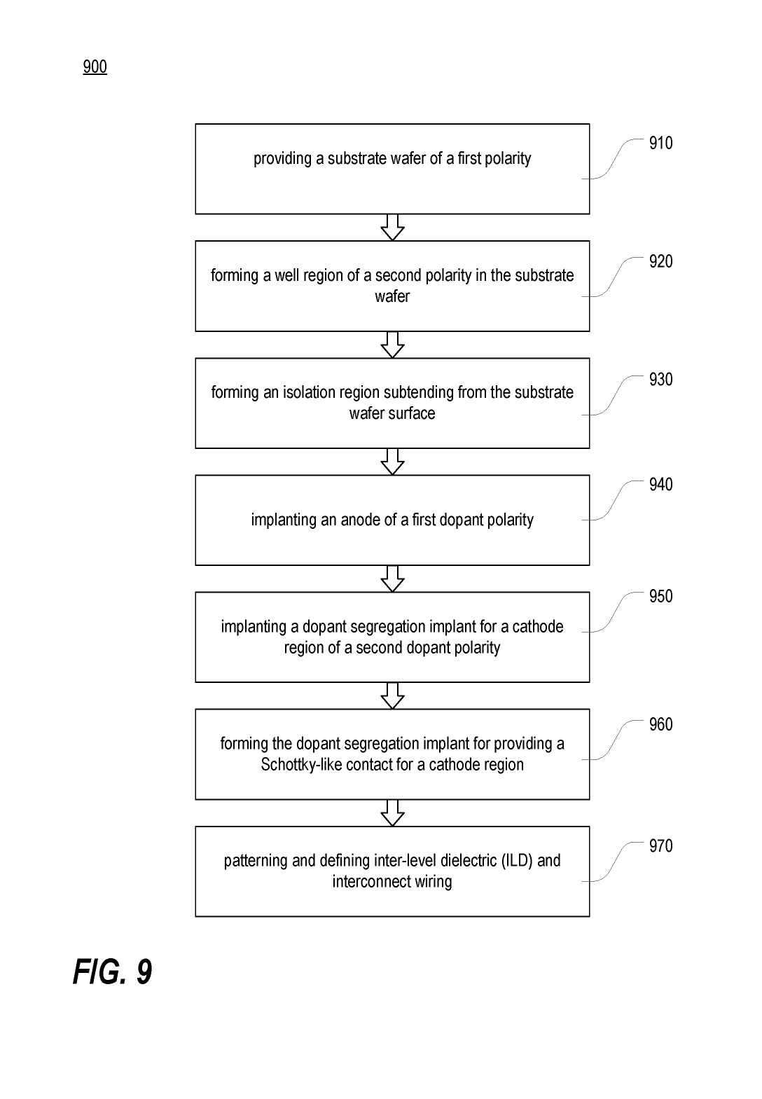

FIG. 9 is a flowchart illustrating a method 900 of forming a Shallow trench isolation Schottky Barrier diode (STISBD) structure in accordance with one or more preferred embodiments of the present invention. As shown therein, the method 900 includes providing a substrate wafer of a first polarity at step 910, forming a well region of a second polarity in the substrate wafer at step 920, forming an isolation region subtending from the substrate wafer surface at step 930, implanting an anode of the first dopant polarity at step 940, implanting a dopant segregation implant for a cathode region of the second polarity at step 950, forming the dopant segregation implant for providing a Schottky-like contact for the cathode region at step 960, and patterning and defining interlevel dielectric (ILD) and interconnect wiring at step 970.

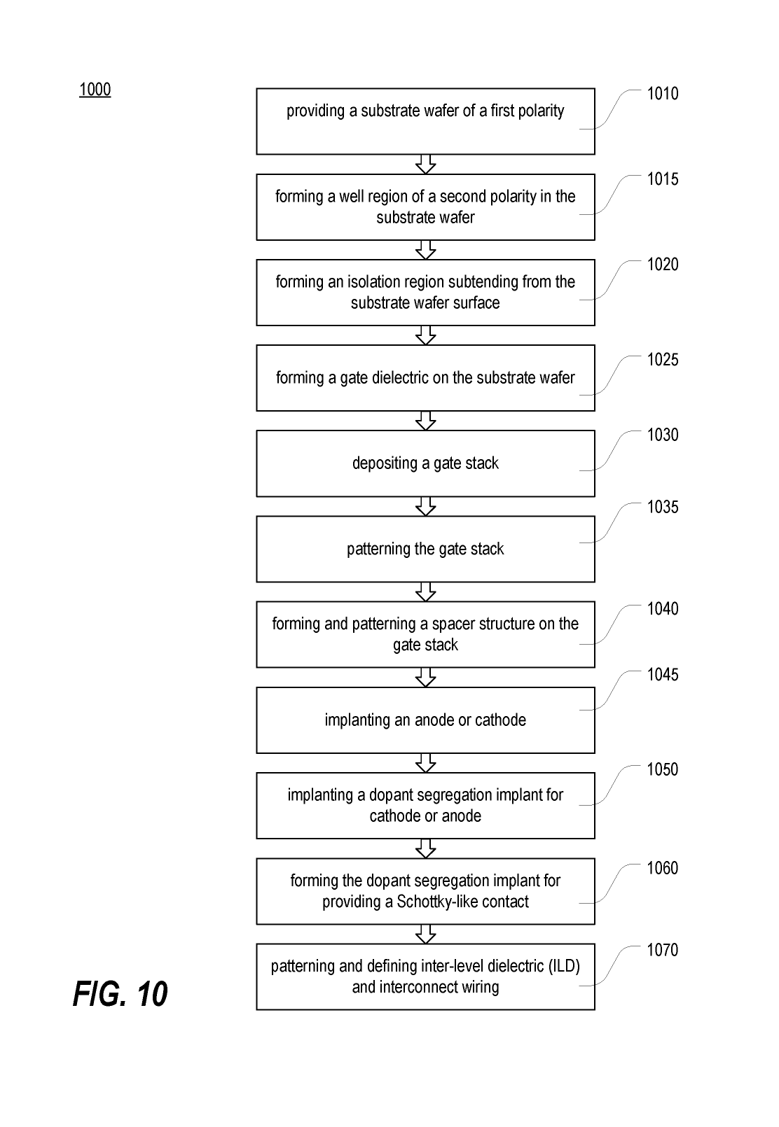

FIG. 10 is a flowchart illustrating a method 1000 of forming a p+/n−/n+ Schottky Barrier Lubistor structure in accordance with one or more preferred embodiments of the present invention. The method 1000 includes providing a substrate wafer of a first polarity at step 1010, forming a well of a second polarity in the substrate wafer at step 1015, forming an isolation region subtending from the substrate wafer surface at step 1020, forming a gate dielectric on the substrate wafer at step 1025, depositing a gate stack at step 1030, patterning the gate stack at step 1035, forming and patterning a spacer structure on the gate stack at step 1040, implanting an anode or cathode at step 1045, implanting a dopant segregation implant for an anode or cathode region at step 1050, forming the dopant segregation implant for providing a Schottky-like contact at step 1060, and patterning and defining interlevel dielectric (ILD) and interconnect wiring at step 1070.

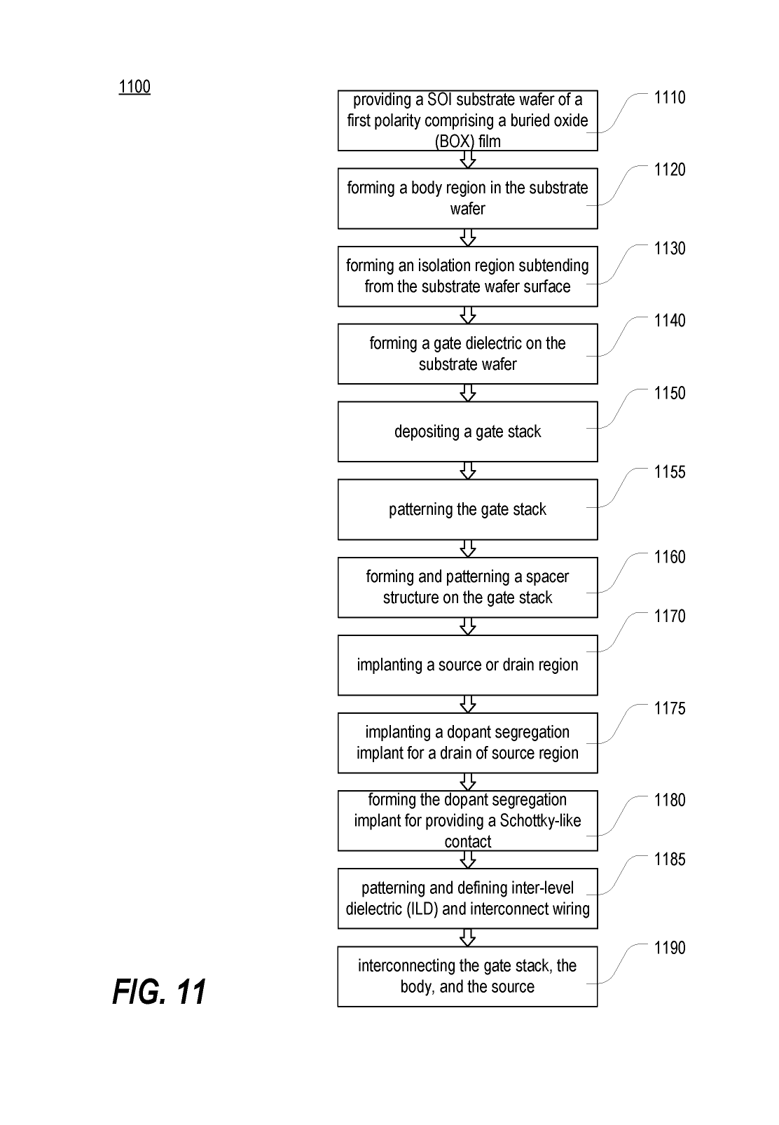

FIG. 11 is a flowchart illustrating a method 1100 of forming a diode-configured Dynamic Threshold Schottky Barrier MOS (DTSBMOS) structure with a Schottky drain and Schottky source in accordance with one or more preferred embodiments of the present invention. The method 1100 includes providing a SOI substrate wafer of a first polarity comprising a buried oxide (BOX) film at step 1110, forming a body region in the substrate wafer at step 1120, forming an isolation region subtending from the substrate wafer surface at step 1130, forming a gate dielectric on the substrate wafer at step 1140, depositing a gate stack at step 1150, patterning the gate stack at step 1155, forming and patterning a spacer structure on the gate stack at step 1160, implanting a source or drain region at step 1170, implanting a dopant segregation implant for a source or drain region at step 1175, forming the dopant segregation implant for providing a Schottky-like contact at step 1180, patterning and defining interlevel dielectric (ILD) and interconnects at step 1185, and interconnecting the gate stack, body region, and source region at step 1190.

It is understood that alternate structures and methods exist for establishing equivalent MOSFET devices. Alternate rectifying contacts can include pure metal source (and/or drain) without the interfacial dopant segregation layer. Alternate silicides can be utilized without an interfacial dopant segregation layer. These can be inclusive of refractory metals such Co, Ni, Ni/Pt, Pd, Pt, Ta, TaN, Ti, TiN, and W. The rectifying contacts can include pure metal source/drains with interfacial insulating layers.

A further additional embodiment for processing with CMOS and/or BiCMOS elements is performing the depositions of the CMOS silicide and the Schottky or Schottky-like contact silicide and performing a single thermal process step for both silicides. For the case where a single thermal processing step is used for the silicides, an additional embodiment is performing the dopant segregation implant before the CMOS silicidation.

In radio frequency (RF) circuit applications, isolation can be introduced between circuit elements, power rails, and core domains to avoid electrical overstress (EOS) from electrostatic discharge (ESD), latchup, and electromagnetic interference (EMI). Isolation can be introduced between bond pads, transmitter, and receiver network. This can be achieved using capacitive isolation, inductive isolation or both capacitive and inductive isolation.

Inductive isolation can be introduced using devices such as shunt inductors, baluns, and some other transformers or other devices as part of the ESD protection scheme. These can be introduced between bond pads and the ESD elements discussed in this disclosure. Shunt inductors can be place between the bond pad and ground. At ESD frequencies, the ESD current will be shunted to ground, avoiding failure to the ESD RF elements and RF circuitry. Inductive isolation can also introduce a transformer, where the input bond pad of the RF network is connected to the input coil of the transformer, and the output coil of the transformer are connected to the devices in the disclosure. Using this balun configuration, the EOS current can be discharged to ground.

Capacitive isolation can also be introduced by placement of a dielectric to create capacitance coupling to introduce alternate current coupling. This can be used to provide ESD and EOS protection in RF networks combined with ESD element. The capacitance coupling can be placed between bond pad and ESD circuitry, chip-to-chip, or chip domain-to-chip domain. The capacitive isolation can be introduced by a single capacitor component, or a dielectric film and two metal plates where the dielectric can be the inter-level dielectric, a buried oxide (BOX) layer, or thin-film dielectric film. Capacitors can be placed in a series configuration to introduce capacitive de-coupling. Different capacitors will provide different levels of ESD protection. A thin oxide capacitor will provide 200V human body model (HBM) levels. A vertical parallel plate (VPP) capacitor can achieve 1000 V HBM ESD levels. This can be placed in series with the ESD network elements.

Inductor and capacitor elements in series and parallel configurations with the ESD device elements to provide ESD and EOS protection for RF networks. Inductor shunts (e.g. to ground) and capacitor series elements can be used in combination to provide added ESD protection with the ESD diode elements.

Additionally, inductor and capacitor elements can be used in parallel to form LC tanks for ESD protection. If the resonance frequency of the LC tank is set to the application frequency, then the impedance of the LC tank is infinite. By placing an LC tank in series with the ESD diode elements (e.g. between the ESD diode and the power rails), the impedance of the ESD loading is negligible.

It will be understood by those skilled in the art that the embodiments can be implemented in wafer materials commonly used in the industry such as bulk silicon, SOI, SiC, GaN, GaAs, InP, etc. The use of a particular starting material or material system should not be limited to those explicitly specified. The objective is to be able to build rectifying barrier junctions within the wafer, thus typical semiconductor-based starting material should be considered. Likewise, the isolation scheme used for isolating active devices or regions within the semiconductor starting material could include, but is not limited to, self-isolation, junction isolation, shallow-trench isolation (STI), dielectric isolation, etc.

It should be noted that the description and drawings merely illustrate the principles of the proposed methods and systems. It will thus be appreciated that those skilled in the art will be able to devise various arrangements that, although not explicitly described or shown herein, embody the principles of the invention and are included within its spirit and scope. Furthermore, all examples recited herein are principally intended expressly to be only for pedagogical purposes to aid the reader in understanding the principles of the proposed methods and systems and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass equivalents thereof.

In one or more embodiments, various advantages may be conferred, although not every embodiment necessarily offers every such advantage. In one or more embodiments, a solution is provided to address a device with low on-resistance. In one or more embodiments, a solution is provided to address a device with a low turn-on voltage. In one or more embodiments, solution is provided to address a device with less semiconductor chip area. In one or more embodiments, a solution is provided to address a device with lower capacitance. In one or more embodiments, a device and circuit are provided having improved device reliability. In one or more embodiments, a device and circuit are provided having reduced bipolar current gain of its parasitic bipolar junction transistor (BJT). In one or more embodiments, a device and circuit are provided having improved ESD robustness. In one or more embodiments, a device and circuit are provided having improved ESD robustness per loading capacitance ratio. In one or more embodiments, a device and circuit are provided having reduced sensitivity to CMOS latchup.

Based on the foregoing information, it is readily understood by those persons skilled in the art that the present invention is susceptible of broad utility and application. Many embodiments and adaptations of the present invention other than those specifically described herein, as well as many variations, modifications, and equivalent arrangements, will be apparent from or reasonably suggested by the present invention and the foregoing descriptions thereof, without departing from the substance or scope of the present invention.

Accordingly, while the present invention has been described herein in detail in relation to its preferred embodiment, it is to be understood that this disclosure is only illustrative and exemplary of the present invention and is made merely for the purpose of providing a full and enabling disclosure of the invention. The foregoing disclosure is not intended to be construed to limit the present invention or otherwise exclude any such other embodiments, adaptations, variations, modifications or equivalent arrangements; the present invention being limited only by the claims appended hereto and the equivalents thereof. Although specific terms are employed herein, they are used in a generic and descriptive sense only and not for the purpose of limitation.

What is claimed is:

1. A diode structure comprising:
a substrate defining a wafer surface;
a well region formed on or within said substrate;
an isolation structure substantially near said substrate wafer surface;
an anode, of a first dopant polarity, defined by said isolation structure in said well region formed on or within said substrate;
a cathode, of a second dopant polarity, defined by said isolation structure; and
a rectifying contact on at least one of the anode and the cathode, wherein the rectifying contact is a Schottky or Schottky-like contact formed substantially near the wafer surface.

2. The diode structure of claim 1, wherein said isolation structure includes a shallow trench isolation (STI) structure having a surface, wherein the surface of said isolation structure is substantially co-planar to said substrate wafer surface.

3. The diode structure of claim 1, wherein said isolation structure includes a gate structure and a spacer structure.

4. The diode structure of claim 3, wherein said diode structure is a polysilicon-gate defined diode Lubistor structure.

5. The diode structure of claim 3, wherein the Schottky or Schottky-like contact is a pure metal, a pure metal alloy, or a silicide-to-semiconductor interface.

6. The diode structure of claim 3, wherein the Schottky or Schottky-like contact is substantially near said gate structure to provide reduced electrical resistance relative to a conventional p-n diode structure.

7. The diode structure of claim 3, wherein the Schottky or Schottky-like contact provides reduced electrical capacitance relative to a conventional p-n diode structure.

8. The diode structure of claim 3, wherein the spacer structure abuts a sidewall of said gate structure and adjusts the electrical coupling to the rectifying contact.

9. The diode structure of claim 3, wherein the Schottky or Schottky-like contact has a band structure that is modulated with anneal parameters, and wherein the anneal parameters comprise a temperature and/or a time.

10. The diode structure of claim 3, wherein the Schottky or Schottky-like contact has a band structure that is modulated by dopant segregation implantation dose and/or dopant segregation implantation energy.

11. The diode structure of claim 3, wherein the rectifying contact is formed from a refractory metal, and wherein said refractory metal includes one or more of Co, Ni, Ni/Pt, Pd, Pt, Ta, TaN, Ti, TiN, and W.

12. The diode structure of claim 3, wherein said well region has a dopant polarity that is the same dopant polarity as the cathode, thereby providing a p+/n−/n+ diode.

13. The diode structure of claim 3, wherein said well region has a dopant polarity that is the same dopant polarity as the anode, thereby providing a p+/p−/n+ diode.

14. The diode structure of claim 3, wherein said well region includes a first well region and a second well region, wherein the first well region has a dopant polarity that is the same dopant polarity as the anode, and wherein the second well region has a dopant polarity that is the same dopant polarity as the cathode, thereby providing a p+/p−/n−/n+ diode.

15. A diode structure comprising:
a silicon on insulator (SOI) wafer that includes a substrate, supporting a buried oxide (BOX) layer and a silicon film above said BOX layer, and defining a wafer surface;
a gate structure and a spacer structure on said silicon on insulator (SOI) wafer;
a region of a first dopant polarity, forming an anode, defined by said gate structure and spacer structure, formed in said SOI wafer;
a region of a second dopant polarity, forming a cathode, defined by said gate structure and spacer structure; and
a rectifying contact on at least one of the anode and the cathode, wherein the rectifying contact is a Schottky or Schottky-like contact formed substantially near the wafer surface.

16. The diode structure of claim 15, wherein the Schottky or Schottky-like contact is substantially near said gate structure to provide reduced electrical resistance relative to a conventional p-n diode structure.

17. The diode structure of claim 15, wherein the spacer structure abuts a sidewall of said gate structure and adjusts the electrical coupling to the rectifying contact.

18. The diode structure of claim 15, wherein said diode structure provides a p+/n−/n+ diode.

19. The diode structure of claim 15, wherein said diode structure provides a p+/p−/n+ diode.

20. The diode structure of claim 15, wherein said diode structure provides a p+/p−/n−/n+ diode.

21. A dynamic threshold Schottky Barrier MOS (DTSBMOS) comprising:
a silicon on insulator (SOI) wafer that includes a substrate, supporting a buried oxide (BOX) layer and a silicon film above said BOX layer, wherein said silicon film forms a body of a first dopant polarity, and defining a wafer surface;
a gate structure and a spacer structure on said silicon on insulator (SOI) wafer;
a source region of a second dopant polarity defined adjacent to said gate structure;
a drain region of the second dopant polarity defined adjacent to said gate structure; and
a rectifying contact on at least one of the source and the drain region, wherein the rectifying contact is a Schottky or Schottky-like contact formed substantially near the wafer surface;
wherein said gate structure and said body are electrically interconnected.

22. The dynamic threshold Schottky Barrier MOS (DTSBMOS) of claim 21, wherein said gate structure and said body are electrically connected to said source to form a dynamic threshold Schottky Barrier MOS diode.

23. The dynamic threshold Schottky Barrier MOS (DTSBMOS) of claim 22, wherein the Schottky or Schottky-like contact on the drain region is a first Schottky or Schottky-like contact, and wherein a second Schottky or Schottky-like contact is formed on the source region.

24. The dynamic threshold Schottky Barrier MOS (DTSBMOS) of claim 23, wherein said silicon on insulator (SOI) wafer is an ultra-thin SOI (UTSOI) wafer.

25. The dynamic threshold Schottky Barrier MOS (DTSBMOS) of claim 21, wherein the Schottky-like contact is substantially near said gate structure to provide reduced electrical resistance relative to a conventional p-n diode structure.

26. The dynamic threshold Schottky Barrier MOS (DTSBMOS) of claim 21, wherein the spacer structure abuts a sidewall of said gate structure and adjusts the electrical coupling to the rectifying contact.

27. The dynamic threshold Schottky Barrier MOS (DTSBMOS) of claim 21, wherein the Schottky or Schottky-like contact has a band structure that is modulated with anneal parameters, and wherein the anneal parameters comprise a temperature and/or a time.

28. The dynamic threshold Schottky Barrier MOS (DTSBMOS) of claim 21, wherein the Schottky or Schottky-like contact has a band structure that is modulated by dopant segregation implantation dose and/or dopant segregation implantation energy.

29. A method of forming a Shallow Trench Isolation Schottky Barrier diode (STISBD) structure, comprising the steps of:
providing a silicon on insulator (SOI) wafer that includes a substrate, supporting a buried oxide (BOX) layer and a silicon film above said BOX layer, and defining a wafer surface;
forming a gate structure and a spacer structure on said silicon on insulator (SOI) wafer;
forming an anode region, of a first dopant polarity, in the SOI wafer;
forming a cathode region, of a second dopant polarity, in the SOI wafer, wherein the anode and the cathode are defined by said gate structure and spacer structure; and
forming a rectifying contact on at least one of the anode and the cathode, wherein the rectifying contact is a Schottky or Schottky-like contact formed substantially near the wafer surface.
